(19) United States
(12) Patent Application Publication
(10) Pub. No.: US 2012/0033416 A1
(43) Pub. Date: Feb. 9, 2012

(54) PORTABLE POWER MODULE ASSEMBLY

(76) Inventor: Jay A. Ballard, Springville, UT (US)

(21) Appl. No.: 13/205,485

(22) Filed: Aug. 8, 2011

Related U.S. Application Data
(60) Provisional application No. 61/400,997, filed on Aug. 6, 2010.

(51) Int. Cl. F21L 4/04; H01M 2/10; H05K 7/14

(52) U.S. Cl. 362/202; 307/149; 429/99

(57) ABSTRACT

According to one embodiment, an apparatus includes a power module that includes a power source. The apparatus also includes a power consumption module that is configured to consume power from the power source. Further, the apparatus includes a power control module that is configured to selectively regulate power from the power source to the power consumption module. Each of the power module, power consumption module, and power control module includes a positive power terminal, a negative power terminal, and at least one neutral terminal. The power module, power consumption module, and power control module each is removably interconnected adjacently to at least another of the power module, power consumption module, and power control module via engagement between the positive power terminals of the at least one adjacent module, the negative power terminals of the at least one adjacent module, and the neutral terminals of the at least one adjacent module.

### CROSS-REFERENCE TO RELATED APPLICATION

This application claims the benefit of U.S. Provisional Patent Application No. 61/400,997, filed Aug. 6, 2010, which is incorporated herein by reference.

### FIELD

The subject matter of the present disclosure is related generally to portable power consumption devices, and more particularly to a portable power consumption device with a plurality of interconnected modules.

### BACKGROUND

Conventional portable power consumption devices, such as flashlights, GPS tracking units, cameras, emergency beacons, etc., are commonly used in the art for a variety of purposes. Typically, such portable power consumption devices include a power source, electronics that operate on power from the power source, and a switch that controls power to the electronics. Generally, the relative orientation, order, and function of the components of a conventional portable power consumption device are fixed. In other words, once initially configured, known devices are not functionally flexible and easily modifiable. For example, the electrical couplings between the components of known devices are hardwired together making disconnection of the components extremely difficult, if not impossible without permanently damaging or altering the couplings. Accordingly, known devices are not designed to be adaptable or reconfigurable for different applications, needs, or preferences.

Some portable power consumption devices specifically configured for use as a flashlight for emitting light across the visible and non-visible light spectrum fail to adequately provide a non-visible light beam profile that is wide enough for certain environments. Also, certain portable power consumption devices fail to provide adjustability over a broad enough focal range to meet all or most of the requirements associated with certain types of applications.

Additionally, certain known power consumption devices designed for attachment to another object, such as a firearm, are not amenable for attachment to both left-handed and right-handed firearm use. For example, some devices intended for use in a specific orientation are undesirably reoriented when using the device for left-handed operation. Additionally, many firearms, specifically those used by military personnel, have multiple attachment points that introduce orientation difficulties for power consumption devices when the devices have fixed attachment mechanisms.

Some prior art flashlight and lantern devices have attempted to promote flexibility and modularity. For example, some devices include a secondary flashlight that is attachable to a primary flashlight. The secondary flashlight may utilize the power supply from the primary flashlight, but there is no additional interface or interaction between the secondary and primary flashlight.

Other prior art devices have attempted to provide multiple sub-devices attached to each other in a stacked arrangement. The sub-devices each are fully operable discrete devices that may utilize a common power supply incorporated into a single sub-device. Other than the common power supply, the stacked discrete sub-devices do not share other electronics, interfaces, or communication channels. The stackable nature of the prior art sub-devices is simply an attempt to provide a convenient method of co-locating and recharging multiple sub-devices.

### SUMMARY

The subject matter of the present application has been developed in response to the present state of the art, and in particular, in response to the problems and needs in the art that have not yet been fully solved by currently available portable power consumption devices. Accordingly, the subject matter of the present application has been developed to provide a portable power module assembly that overcomes at least some shortcomings of the prior art devices. For example, described herein is one embodiment of a portable power module assembly with a power module, power consumption module, and power control module that are removably interconnected and interchangeable to accommodate various applications, needs, and preferences. Because each module includes matching mechanical and electrical interface points, including electrical leads extending along the entire length of the power module, the modules can be easily reordered relative to each other, replaced with different modules, or supplemented with additional modules.

In certain implementations, the power consumption module is a light-emitting module with two optically-modified narrow profile non-visible light LEDs and an unmodified wide profile non-visible light LED. According to some implementations, the portable power module assembly includes a housing relative to which a power source, the power consumption module, and power control module are rotatable. The relative rotation of the power source, modules, and housing, allow the orientation of the modules to be adjusted to achieve similar results when the housing is in multiple orientations.

Unlike prior art devices, the portable power module assembly of the present application is configured to facilitate the reconfiguration of the modules of the assembly for different applications, needs, or preferences.

According to one embodiment, an apparatus includes a power module that includes a power source. The apparatus also includes a power consumption module that is configured to consume power from the power source. Further, the apparatus includes a power control module that is configured to selectively regulate power from the power source to the power consumption module. Each of the power module, power consumption module, and power control module includes a positive power terminal, a negative power terminal, and at least one neutral terminal. The power module, power consumption module, and power control module each is removably interconnected adjacently to at least another of the power module, power consumption module, and power control module via engagement between the positive power terminals of the at least one adjacent module, the negative power terminals of the at least one adjacent module, and the neutral terminals of the at least one adjacent module. The positive power terminals of the power module, power consumption module, and power control module are electrically coupleable to each other via the engagement between the positive power terminals of adjacent modules. Further, the negative power terminals of the power module, power consumption module, and power control module are electrically coupleable to each other via the engagement between the positive power terminals of adjacent modules. Also, the neutral terminals of the power module, power consumption module, and power control module are electrically coupleable to each other via the engagement between the neutral power terminals of adjacent modules.

In certain implementations of the apparatus, the power control module selectively regulates power from the power source to the power consumption module via communication through the neutral terminals of at least the power consumption module and the power control module. The power module can be positionable between and removably interconnected adjacently to the power consumption module and the power control module. Also, the power control module can be positionable between and removably interconnected adjacently to the power module and power consumption module. The control module may include a switch that is selectively actuatable between at least two positions associated with at least two power regulating modes.

According to some implementations of the apparatus, the power consumption module includes a light emitting element.

In yet certain implementations of the apparatus, the power consumption module is a first power consumption module. The apparatus can further include a second power consumption module that is removably interconnected adjacently to at least one of the power module, first power consumption module, and power control module in any of a plurality of sequences. The first power consumption module can be interchangeable with the second power consumption module.

In some implementations of the apparatus, the power control module is a first power control module. The apparatus can further include a second power control module configured to regulate power from the power source to the first power control module. The second power control module can be removably interconnected adjacently to at least one of the power module, first power consumption module, and power control module in any of a plurality of sequences. The second power control module may include a power interrupter portion and a switch portion. The power interrupter portion can include the positive power terminal, negative power terminal, and at least one neutral terminal of the second power control module. The switch portion can be operable to control operation of the power interrupter portion and is positionable remotely relative to the power interrupter portion. In certain implementations, the first and second power control modules are interchangeable with each other.

In some implementations, the first power control module can be operable to control power in one of at most a first number of modes and the second power control module that is interchangeable with the first power control module can be operable to control power in a second number of modes greater than the first number. In one implementation, the first power control module can be operable to control power in one of at most three modes, and the second power control module that is interchangeable with the first power control module can be operable to control power in at least four modes. Alternatively, in another implementation, the first power control module can be operable to control power in one of at most two modes, and the second power control module that is interchangeable with the first power control module can be operable to control power in at least three modes.

In one implementation, the power module is a first power module, and the apparatus further includes a second power module removably interconnected adjacently to the first power module. The power module, power consumption module, and control module can each be defined about a central axis, and the central axes of the power module, power consumption module, and control module can be coaxially alignable.

According to some implementations of the apparatus, the engaged positive power terminals, negative power terminals, and neutral power terminals of adjacent modules include respective first and second positive power terminals, first and second negative power terminals, and first and second neutral terminals. The first terminals each include one of a male terminal and female terminal, and the second terminals each include the other of the male terminal and female terminals. The male terminals each include a non-electrical projection and an electrical recess positioned within the projection. The female terminals each include a non-electrical recess and an electrical projection positioned within the recess. Engagement between male and female terminals comprises corresponding mating engagement of the non-electrical projection with the non-electrical recess and mating engagement of the electrical projection with the electrical recess.

In yet some implementations of apparatus, the positive power terminals of the power module, power consumption module, and power control module are coaxially alignable, the negative power terminals of the power module, power consumption module, and power control module are coaxially alignable, and the neutral terminals of the power module, power consumption module, and power control module are coaxially alignable. At least one of the positive power terminals, negative power terminals, and neutral terminals of the respective power module, power consumption module, and power control module can be shaped differently than the others of the positive power terminals, negative power terminals, and neutral terminals of the respective power module, power consumption module, and power control module. Engagement between the differently-shaped terminals ensures relative coaxial alignment of the positive power terminals, negative power terminals, and neutral terminals.

In some implementations of the apparatus, the power module, power consumption module, and power control module are removably interconnected adjacently to at least another of the power module, power consumption module, and power control module in any of a plurality of sequences. The power module, power consumption module, and control module can be substantially cylindrically shaped and stackable in an end-to-end configuration. The positive power terminals, negative power terminals, and neutral terminals can be formed in the ends of the modules.

According to yet some implementations, the power module includes a housing within which the power source is positioned. When removably interconnected, the power source, power consumption module, and power control module are co-rotatable relative to the housing of the power module. The apparatus may further include at least two locking mechanisms each configured to selectively lock in place the rotational orientation of the power module, power consumption module, and power control module relative to the housing of the power module. The at least two locking mechanisms may each include a lock ring and a corresponding lock ring engagement feature. The housing of the power module can be symmetrical.

According to some implementations, the power module, power consumption module, and power control module are removably interconnected via respective couplings each including a plurality of interlocking projections and recesses. The housing may have a first length between first and second ends of the housing. The power source can have a second length with the second length being longer than the first length such that respective portions of the power source extend outwardly beyond the first and second ends of the housing

In yet some implementations, each of the power module, power consumption module, and power control module includes at least one connection element separate and distinct from the positive power terminal, negative power terminal, and at least one neutral terminal. Each of the power module, power consumption module, and power control module being removably and securely interconnected adjacently to at least another of the power module, power consumption module, and power control module via engagement between respective connection elements. At least one connection element may include one of a lock ring and lock ring engagement feature such that engagement between respective connection elements comprises engagement between a respective lock ring and lock ring engagement feature. The power module may include a housing within which the power source is positioned, the housing extends between a first end and a second end. The first end of the housing includes a first lock ring engagement feature and the second end includes a second lock ring engagement feature. The power consumption module includes a first lock ring and the power control module includes a second lock ring. The first lock ring is engageable with the first lock ring engagement feature to removably and securely interconnect the power module and the power consumption module, and the second lock ring is engageable with the second lock ring engagement feature to removably and securely interconnect the power module and the power control module.

According to another embodiment, an apparatus for powering a power consumption device includes at least one set of a plurality of battery cells positioned adjacent and parallel to each other. The at least one set of a plurality of battery cells includes a first end and second end opposing the first end with each battery cell including a positive terminal and a negative terminal. The apparatus includes a first end cap positioned at the first end of the at least one set of a plurality of battery cells, and a second end cap positioned at the second end of the at least one set of a plurality of battery cells. The apparatus further includes a plurality of tie rod terminals secured to and extending between the first end cap and the second end cap. The plurality of tie rod terminals are tightenable (e.g., via threaded, soldered, welded, or other mechanical adjoining techniques) to draw the first and second end caps together and secure the at least one set of a plurality of battery cells between the first and second end caps. A first of the plurality of tie rod terminals is electrically coupled to the positive terminals of the battery cells, a second of the plurality of tie rod terminals is electrically coupled to the negative terminals of the battery cells, and a third of the plurality of tie rod terminals is electrically neutral.

In some implementations, the first end cap includes a plurality of recesses. A first end portion of each of the plurality of tie rod terminals secured to the first end cap can extend into a respective recess of the first end cap. The first end portions can be configured to receive female electrical terminals. The second end cap includes a plurality of projections. A second end portion of each of the plurality of tie rod terminals secured to the second end cap can extend through a respective projection of the first end cap. The second end portions can be configured to receive male electrical terminals. At least one of the plurality of recesses and projections has a first cross-sectional shape, and at least another of the plurality of recesses and projections has a second cross-sectional shape different that the first cross-sectional shape. A respective one of the plurality of tie rods extends between the at least one of the plurality of recesses and projections with the first cross-sectional shape, and a respective one of the plurality of tie rods extends between the at least one of the plurality of recesses and projections with the second cross-sectional shape.

According to certain implementations the at least one set of a plurality of battery cells includes an interior space defined between the plurality of battery cells and a plurality of exterior spaces each defined between respective adjacent battery cells of the plurality of battery cells. The first of the plurality of tie rod terminals extends through the interior space, the second of the plurality of tie rod terminals extends through a respective one of the plurality of exterior spaces, and the third of the plurality of tie rod terminals extends through another respective one of the plurality of exterior spaces.

In yet some implementations, the first and second end caps each have a substantially circular outer periphery of equal dimensions. At least one set of a plurality of battery cells and plurality of tie rod terminals are confined within the substantially circular outer peripheries of the first and second caps. At least one set of a plurality of battery cells includes at least a first and second set of a plurality of battery cells each having a first end and a second end. The apparatus may further include a spacer plate positioned between the first and second set of a plurality of battery cells. The plurality of tie rod terminals extends through the spacer plate. The first and second end caps each comprises a plurality of battery spacing tabs configured to engage the plurality of battery cells and maintain the battery cells in a fixed position relative to the first and second end caps.

According to some implementations, the apparatus further includes a housing defining an interior channel within which the at least one set of a plurality of battery cells is positionable. The housing is configured to be secured to the power consumption device and a diameter of the interior channel is approximately equal to a diameter of the first and second end caps. The diameter of the interior channel can be approximately equal to a maximum distance between the outermost peripheries of the plurality of battery cells.

In yet another embodiment, an apparatus for emitting light includes a portable power source and a light emitting module communicable in power receiving communication with the portable power source. The light emitting module includes a first light emitting diode (LED), a second LED, and a third LED. The first LED includes a first optic lens for producing a first modified light beam, the second LED includes a second optic lens for producing a second modified light beam narrower than the first modified light beam, and the third LED is without an optic lens and produces an unmodified light beam wider than the first modified light beam. The first, second, and third LEDs may each be a non-visible light LED. The mounting plane of the third LED can be elevated relative to the mounting planes of the first and second LEDs.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 is a frontal perspective view of a portable power module assembly according to one embodiment;

FIG. 2 is a rearward perspective view of the portable power module assembly of FIG. 1;

FIG. 3 is a side elevation view of the portable power module assembly of FIG. 1;

FIG. 4 is an exploded side elevation view of the portable power module assembly of FIG. 1;

FIG. 5 is a perspective view of a battery pack of a power module showing a female interface according to one embodiment;

FIG. 6 is a perspective view of the battery pack of a power module shown in FIG. 5, but showing a male interface;

FIG. 7 is a front view of the female interface of the battery pack of FIG. 5;

FIG. 8 is a cross-sectional side view of the battery pack of FIG. 7 taken along the line 8-8 of FIG. 7;

FIG. 9 is a cross-sectional end view of the battery pack and housing of the power module shown in FIG. 4 taken along the line 9-9 of FIG. 4;

FIG. 10 is a perspective view of a power consumption module showing a female interface according to one embodiment;

FIG. 11 is a front view of a portable power module assembly according to one embodiment;

FIG. 12 is a cross-sectional side view of the portable power module assembly of FIG. 11 taken along the line 12-12 of FIG. 11;

FIG. 13 is a perspective view of a power consumption module without a protective lens cap according to one embodiment;

FIG. 14 is a perspective view of a power control module showing a male interface according to one embodiment;

FIG. 15 is a schematic illustration of a portable power module assembly according to a first embodiment;

FIG. 16 is a schematic illustration of a portable power module assembly according to a second embodiment;

FIG. 17 is a schematic illustration of a portable power module assembly according to a third embodiment;

FIG. 18 is a schematic illustration of a portable power module assembly according to a fourth embodiment;

FIG. 19 is a schematic illustration of a portable power module assembly according to a fifth embodiment;

FIG. 20 is a schematic illustration of a portable power module assembly according to a sixth embodiment; and

FIG. 21 is a schematic illustration of a portable power module assembly according to a seventh embodiment.

### DETAILED DESCRIPTION

Reference throughout this specification to “one embodiment,” “an embodiment,” or similar language means that a particular feature, structure, or characteristic described in connection with the embodiment is included in at least one embodiment of the subject matter of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the subject matter of the present disclosure, however, absent an express correlation to indicate otherwise, an implementation may be associated with one or more embodiments.

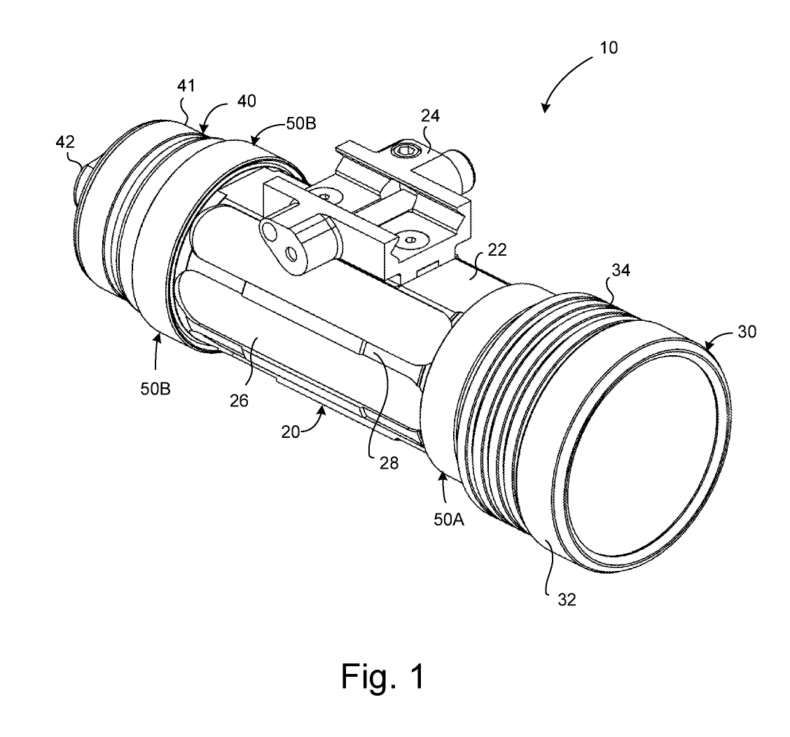

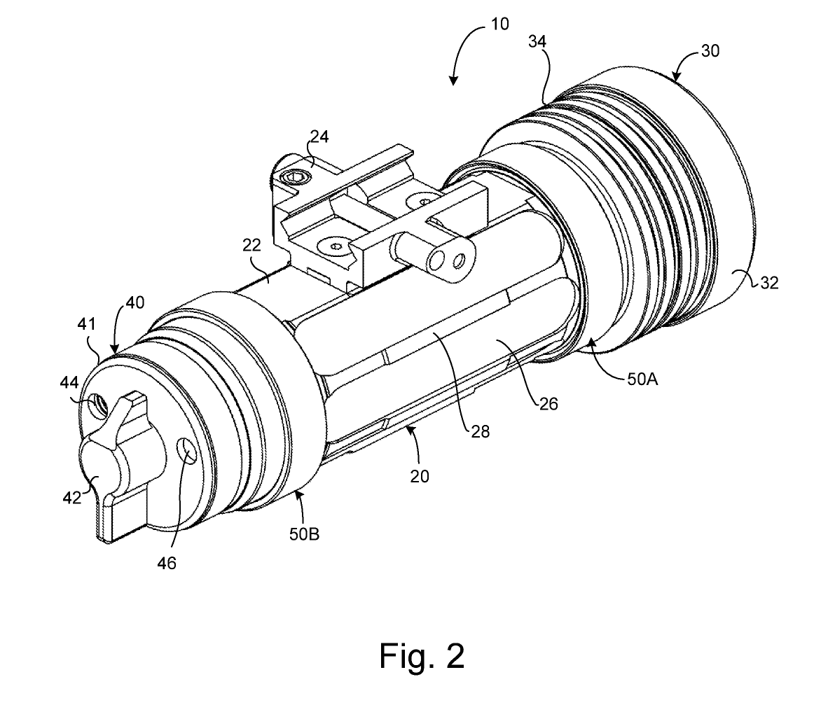

FIGS. 1 and 2 depicts one embodiment of a portable power module assembly 10 that includes a power module 20, power consumption module 30, and power control module 40. Each module 20, 30, 40 is an independent self-contained unit with a well-defined interface that is removably interconnectable to the other modules. Accordingly, the modules 20, 30, 40 are easily disconnectable from and reconnectable to each other without permanent or semi-permanent deformation or alteration of the components of the modules.

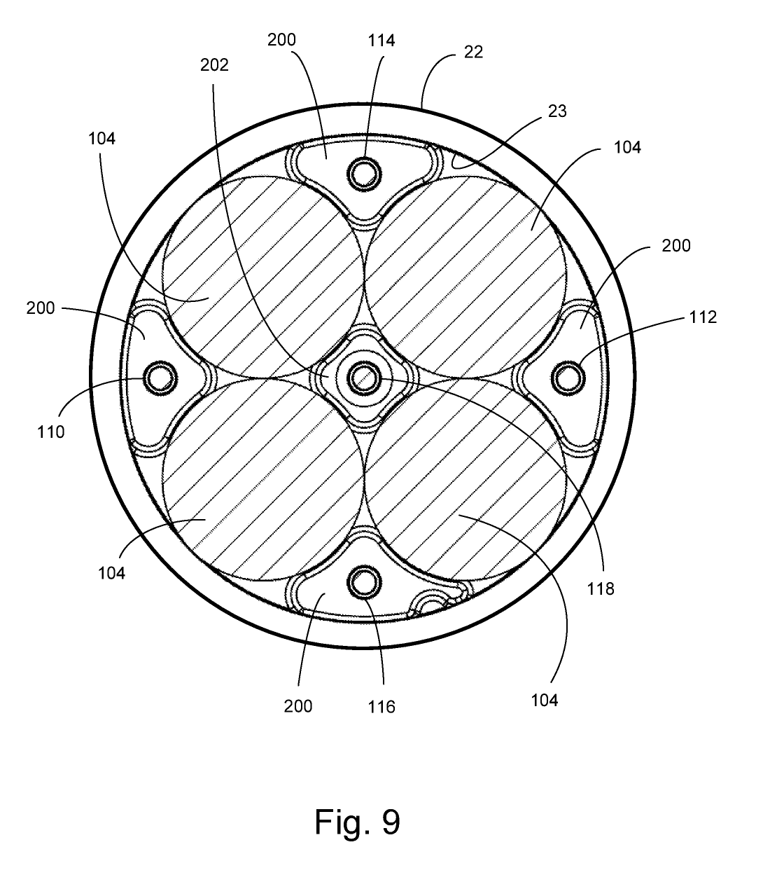

The power module 20 includes a housing 22 that houses a power source. The housing 22 is a generally cylindrically-shaped tubular element defining a hollow interior channel 23 (see FIG. 9). The exterior surface of the housing 22 may include grip-enhancing features, such as a series of alternating planar surfaces 26 and raised textured surfaces 28. The housing 22 can be made from any of various substantially rigid materials, such as, for example, metals, metal alloys, hard plastics, composites, and the like. In certain applications where attachment of the portable power module assembly 10 to ancillary objects, such as firearms, helmets, vehicles, cameras, etc., is desirable, one or more attachment mechanisms 24 can be permanently or removably secured to the housing 22. Such attachment mechanisms 24 may include quick-release components to enable quick and secure attachment of the assembly 10 to and quick removal of the assembly from an ancillary object.

The power consumption module 30 is removably interconnected to the power module 20 in power receiving communication with the power source housed by the housing 22. Generally, the power consumption module 30 includes a housing 34 within which any of various electrically-powered devices is housed. The type of electrically-powered device housed by the housing 34 is selectable according to the particular application or applications for which the portable power module assembly 10 will be used. Accordingly, the power consumption module 30 can include light-emitting devices for illumination applications, GPS devices for geographical tracking applications, beacon signal devices for life-saving applications, sensor devices for chemical composition detection applications, as well as any other devices associated with a desirable application as will be discussed on more detail below. As an example only, the power consumption module 30 in the illustrated embodiments is an illumination module with light-emitting devices. Accordingly, the power consumption module 30 includes a protective, and optionally translucent, lens cap 32 that is removably securable to the housing 34 to protect the devices housed within the housing.

The power control module 40 also is removably interconnected to the power module 20, but in power regulating communication with the power consumption module 30 to control the flow of power from the power module 20 to the power consumption module. Like the power consumption module 30, the power control module 40 includes a housing 41 within which power regulating components are housed. Generally, the power regulating components include electrical switches and/or circuitry communicable in electric communication with the electrically-powered devices of the power consumption module 30.

The power control module 40 includes at least one mechanical actuator 42 coupled with the electrical switches and/or circuitry within the housing 41. The mechanical actuator 42 is selectively actuatable to activate or deactivate the electrical switches and/or circuitry (e.g., closing and opening electrical loops) for providing and regulating power to the power consumption module 30. In certain implementations, the power regulating components of the power control module 40 are configured to facilitate a two-mode operation (e.g., ON and OFF modes) of the power consumption module 30. In such implementations, the mechanical actuator 42 is movable between at least two positions to switch operation of the power consumption module 30 between the two modes. According to some other implementations, the power regulating components of the power control module 30 are configured to facilitate three or more modes of operation (e.g., OFF and multiple ON modes) of the power consumption module 30. The multiple ON modes may include activation of different devices (e.g., multiple light emitting diodes (LED)) or adjusting the power to a single device (e.g., increasing or decreasing the intensity of a light beam emitted from an LED). The mechanical actuator 42 can be a rotatable switch as illustrated, a slidable switch, a depressible button, or other similar mechanical actuator that is capable of toggling between two or more positions or facilitating toggling between multiple power control circuits.

In some embodiments, the power control module 40 includes at least one of a battery recharge port 42 and auxiliary device port 44. The battery recharge port 42 is configured to receive a battery recharge source, such as a wall-mounted AC adapter plug, for recharging the power source of the power module 40. The auxiliary device port 44 is configured to receive a connection from an auxiliary device for powering the auxiliary device with power provided by the power module 20. Although the power control module 40 is shown having two external ports, in other embodiments, the power control module can have fewer or more than two external ports. Further, alternatively, or additionally, the power module 20 and/or power consumption module 30 can include external ports.

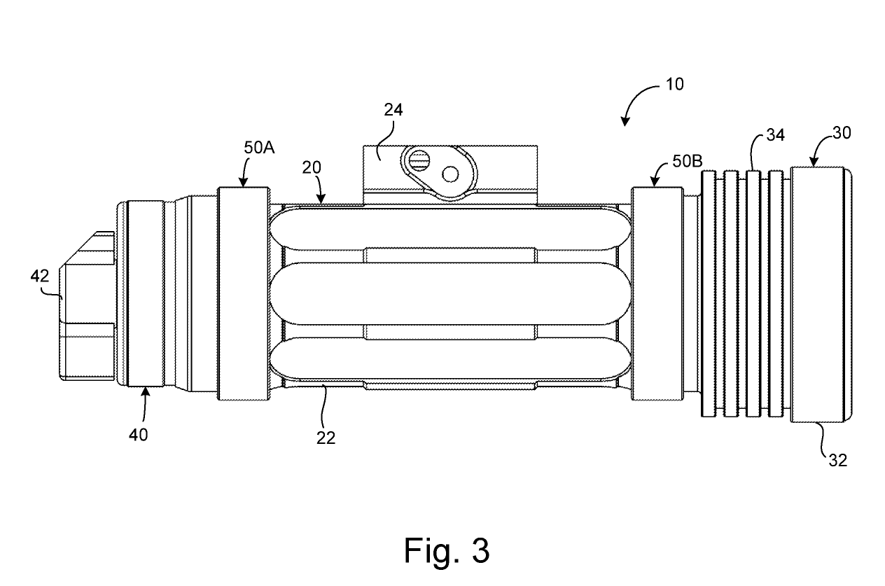

Referring to FIG. 3, the power module 20, power consumption module 30, and power control module 40 can be axially aligned in an end-to-end configuration. As shown, the power module 20 is positioned between and removably connected to both the power consumption and power control modules 30, 40. However, in other embodiments, as will be described later, the position or order of the modules 20, 30, 40 relative to each other can be different. The modules 20, 30, 40 adjacent each other are removably interconnected together via two distinct and independent connections. The first connections are a purely mechanical connection and the second connections are a combination mechanical/electrical connection.

As shown in FIGS. 1-4, the power module 20 is interconnected with the power consumption module 30 via a first purely mechanical connection 50A and with the power control module 40 via a first purely mechanical connection 50B. The first purely mechanical connections 50A, 50B include external threads 52A, 52B formed in the external surface of the housing 22 at respective end portions 27, 29 of the housing. Further, the purely mechanical connections 50A, 50B include corresponding internally-threaded lock rings 54A, 54B rotatably secured to the power consumption module 30 and power control module 40, respectively. The first purely mechanical connections 50A, 50B are formed by threadably engaging the internal threads of the lock rings 54A, 54B with the external threads 52A, 52B of the housing 22. As the lock rings 54A, 54B are tightened relative to the external threads 52A, 52B, the ends of the module housings 34, 41 are pressed against the end portions 27, 29 of the power module housing 22 to form a seal between the housings.

In certain implementations, each end of the power consumption and control module housings 34, 41 includes a groove configured to receive a sealing element 141, such as a gasket or O-ring. The sealing element deforms under pressure from respective end portions 27, 29 of the housing 22 as the first mechanical connections 50A, 50B are tightened to create a more robust seal between the modules. Although in the illustrated embodiments, the lock rings 54A, 54B are rotatably coupled to the power consumption and control modules 30, 40, and the external threads 52A, 52B are formed in the power module housing 20, in other embodiments, the components of the first mechanical connections 50A, 50B can be reversed. In other words, in some embodiments, the lock rings 54A, 54B can be rotatably coupled to the power module housing 20, and the external threads 52A, 52B can be formed in the power consumption and control modules 30, 40.

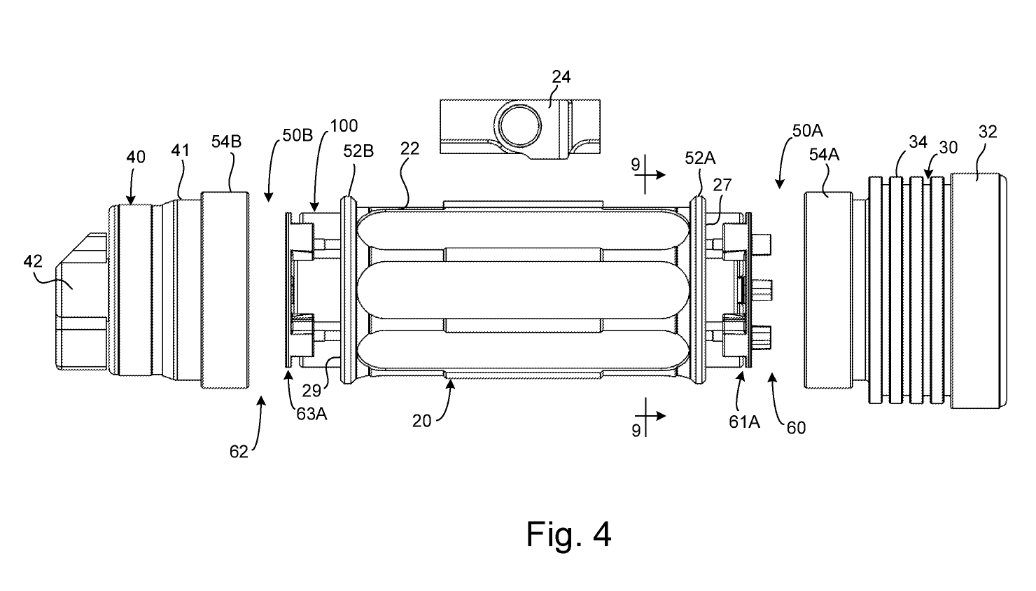

In the illustrated embodiments, as shown in FIG. 4, the housing 22 is symmetrical to facilitate attachment of the power consumption and control modules 30, 40 to either of the end portions 27, 29. Such a configuration promotes ease of assembly. Additionally, the symmetrical configuration of the housing 22 allows the housing to simply be flipped when a reverse orientation of an attachment mechanism (e.g., attachment mechanism 24) is desired, such as when the assembly 10 is detached from a firearm for right-handed use and attached to the same or another firearm for left-handed use.

Additionally, as described above, the power module 20 is interconnected with the power consumption module 30 via a second combination mechanical/electrical connection 60 and with the power control module 40 via a second combination mechanical/electrical connection 62. Generally, each mechanical/electrical connection 60, 62 includes mating engagement between a male interface and a female interface. The male interface includes a plurality of male terminals each having an electrically non-conductive projection formed about an electrically conductive recess. The female interface includes a corresponding plurality of female terminals each having an electrically conductive projection extending into an electrically non-conductive recess. Each mechanical/electrical connection 60, 62 is formed when the electrically non-conductive projections of the male interface are nestably engaged with corresponding electrically non-conductive recesses of the female interface, and the electrically conductive projections of the female interface are inserted into the electrically conductive recesses of the male interface.

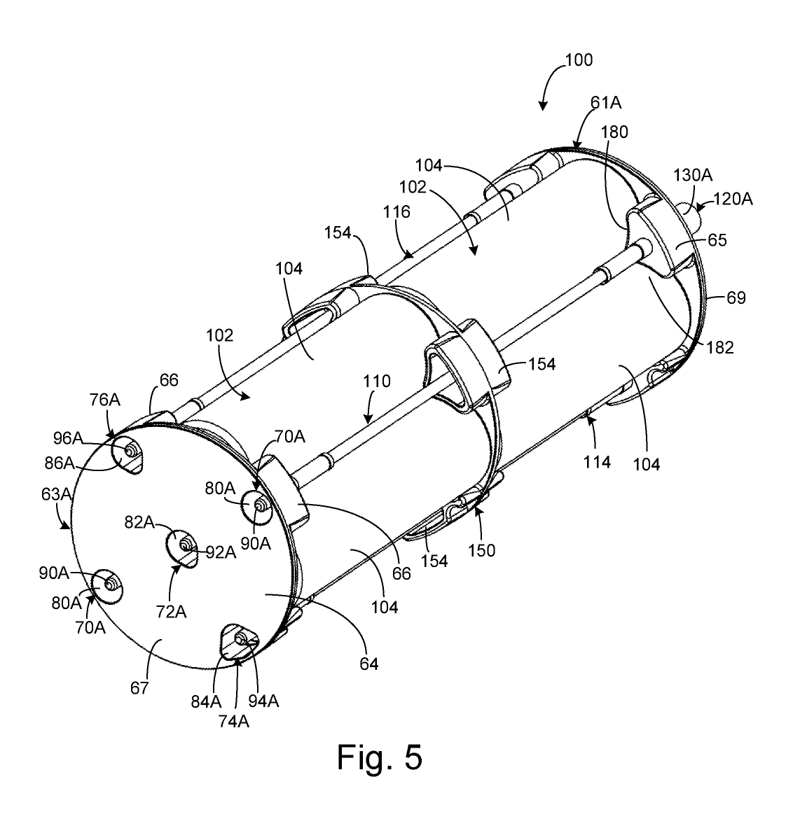

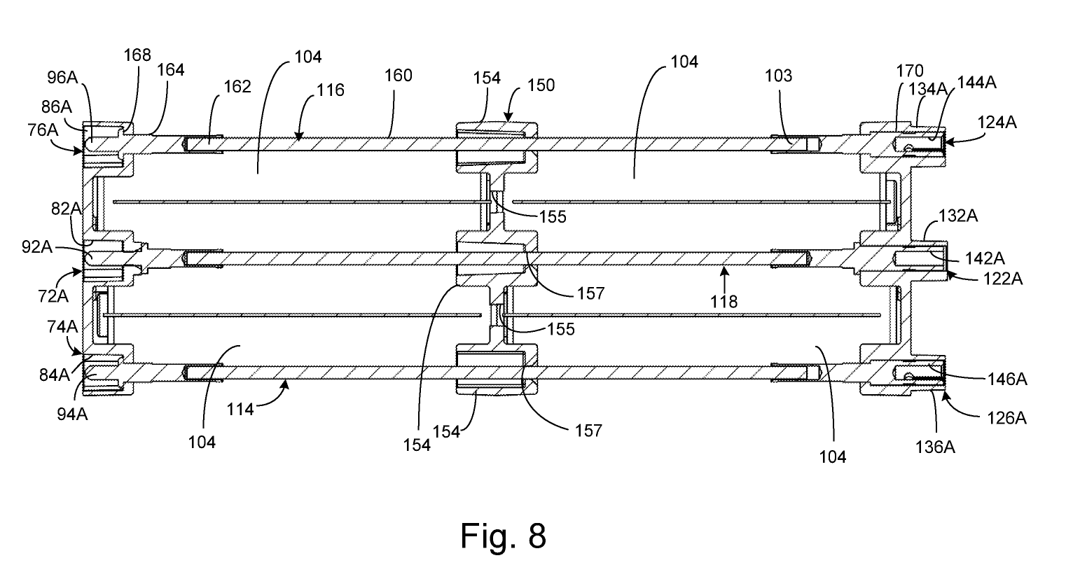

Referring to FIGS. 5-9, and representative of the male and female interfaces of the power consumption and control modules, the power source or battery pack 100 of the power module 20 includes a male interface 61A and a female interface 63A. As shown in FIG. 5, the female interface 63A includes a first end cap 64 with a plurality of female terminals 70A, 72A, 74A, 76A. The female terminals 70A, 72A, 74A, 76A each include a respective recess 80A, 82A, 84A, 86A formed in an outwardly facing surface 67 of the end cap 64. The recesses are positioned about the surface 67 of the cap 64 in an arrangement corresponding with the configuration of battery cells 104 and tie rods 110, 112, 114, 116 as will be described below in more detail. At least one of the recesses has a cross-sectional shape different than the other recesses such that the differently shaped recess or recesses acts as an alignment or keyed feature to ensure proper alignment of the battery pack 100 relative to the power control module 40. In the illustrated embodiment, the recesses 80A have a circular cross-sectional shape, the recesses 82A, 86A have a first non-round cross-sectional shape, and the recess 84A has a second non-round cross-sectional shape different than the first. Although in the illustrated embodiment, the female interface 63A includes two circular recesses, two non-circular recesses of a first shape, and one non-circular recess of a second shape, in other embodiments, the female interface can have any number of circular and/or non-circular recesses as long as at least one recess has a cross-sectional shape different than another recess.

The cap 64 is made from a non-conductive material, such as a plastic. Accordingly, the walls of the recesses 80A, 82A, 84A, 86A, which are formed in the cap 64, also are made from a non-conductive material. Each female terminal 70A, 72A, 74A, 76A also includes a conductive projection or pin 90A, 92A, 94A, 96A extending outwardly into the associated recess from a bottom surface of the recess. The projections 90A, 92A, 94A, 96A form a first tip or end of a respective tie-rod 110, 112, 114, 116 extending the length of the battery pack to the male interface 61A (see, e.g., FIG. 5). As will be explained in more detail below, the second or opposing tip or end of the tie-rods 110, 112, 114, 116 (e.g., conductive recess 140A) is coupled with and extends into a respective projection of the male interface 61A.

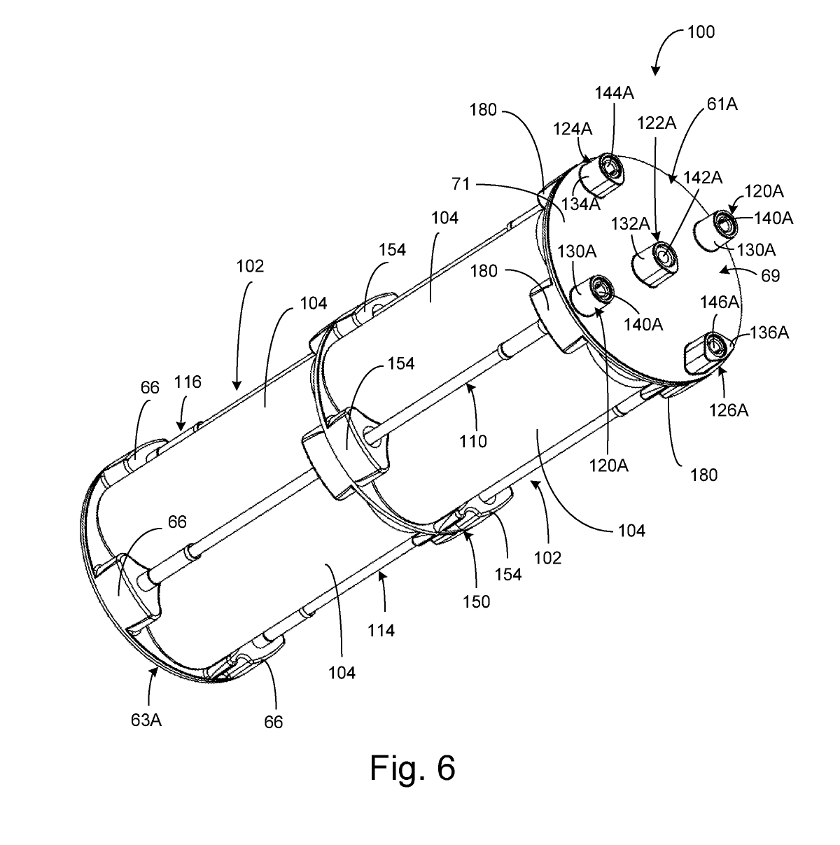

Referring to FIG. 6, the male interface 61A includes a second end cap 69 with a plurality of male terminals 120A, 122A, 124A, 126A corresponding to the number of female terminals 70A, 72A, 74A, 76A of the female interface 63A. The male terminals 120A, 122A, 124A, 126A each include a respective projection 130A, 132A, 134A, 136A extending from an outwardly facing surface 71 of the end cap 69. Like the recesses, at least one of the projections 130A, 132A, 134A, 136A has a cross-sectional shape different than the other projections such that the differently shaped projection or projections acts as an alignment or keyed feature to ensure proper alignment of the battery pack 100 relative to the power consumption module 30. The cross-sectional shapes of the projections 130A, 132A, 134A, 136A correspond with the cross-sectional shapes of the recesses 80A, 82A, 84A, 86A, respectively. Additionally, the projections 130A, 132A, 134A, 136A are positioned about the surface 71 of the cap 69 in the same arrangement as the recesses 80A, 82A, 84A, 86A on the end cap 64 such that each projection is axially alignable with a matching one of the recesses having the same cross-sectional shape.

Each tie-rod (see, e.g., tie-rods 110, 112, 114, 116, 118 of FIGS. 5 and 6) extends axially along the battery pack 100 between respective axially aligned recesses and projections of the same shape and position such that the female terminals 70A 72A 74A, 76A are electrically coupled to respective male terminals 120A, 122A, 124A, 126A via a respective one of the tie-rods 110, 112, 114, 116, 118. Although in the illustrated embodiment, the battery pack 100 includes five female and male terminal sets including one positive terminal set, one negative terminal set, and three neutral terminal sets, in other embodiments, the battery pack can have fewer or more than five female and male terminal sets. For example, in one embodiment, the battery pack includes three female and male terminal sets including one positive terminal set, one negative terminal set, and one neutral terminal set. According to another example, in one embodiment, the battery pack includes two positive terminal sets, two negative terminal sets, and at least one neutral terminal set.

The tie-rods of the battery pack 100 are efficiently positioned within spaces defined between the battery cells 104. In the illustrated embodiments, the battery pack 100 includes sets 102 of four battery cells 104 such that the battery cells define four outer interstitial spaces 200 and one inner interstitial space 202. Each outer interstitial space 200 is defined between the outward-facing surfaces of adjacent battery cells 104 and an outer periphery of the end caps 64, 69 (see, e.g., FIG. 9). In this manner, the entirety of the battery cells 104 and tie-rods remains within the confines of the outer periphery of the end caps 64, 69. The inner interstitial space 202 is defined between the inward-facing surfaces of all four of the battery cells 104. As shown, each of the tie-rods 110, 112, 114, 116 is positioned within and extends along a respective one of the outer interstitial spaces 200 and the tie-rod 118 is positioned within and extends along the inner interstitial space 202.

As shown in FIG. 9, the end caps 64, 69, and spacer 150, each define a circular outer periphery having a diameter just smaller than the inner diameter of the power module housing 22. With the battery pack 100 configured in this manner, the battery pack is substantially supported within the housing 22, but is allowed to rotate freely relative to the housing.

Although the battery pack 100 of the illustrated embodiment includes sets 102 of four battery cells 104, four outer interstitial spaces 200, and one inner interstitial space 202, in other embodiments, the battery pack can include fewer or more than four battery cells to a set, fewer or more than four outer interstitial spaces, and fewer or more than one inner interstitial space. For example, in one embodiment, the battery pack may include one or more sets of three battery cells with one inner interstitial space and three outer interstitial spaces. In such an embodiment, multiple tie-rods can be positioned within and extend along a single outer interstitial space. According to another example, in one embodiment, the battery pack may include one or more sets of five or more battery cells with a plurality of outer battery cells positioned about (e.g., encircling) a single battery cell. In such implementations, the battery pack includes four or more outer interstitial spaces and no inner interstitial spaces.

One of the end caps (e.g., end cap 64) includes electrical circuitry (not shown) such as is commonly known in the art to electrically couple the positive terminals of all the battery cells 104 to one of the female and male terminals of a matching pair of terminals (e.g., the female terminal 72A of the matching pair of female and male terminals 72A, 140A). The other of the female and male terminals (e.g., the male terminal 72A) is then electrically coupled to the positive terminals of all the battery cells via the tie-rod extending between the female and male terminals (e.g., tie-rod 118). In this manner, the tie-rod (e.g., tie-rod 118) extending between the positive female and male terminals (e.g., female and male terminals 74A, 140A) acts as a positive pass-through terminal for providing a positive power connection to both ends of the battery pack 100.

Similarly, the other of the end caps (e.g., end cap 69) includes electrical circuitry (not shown) such as is commonly known in the art to electrically couple the negative terminals of all the battery cells 104 to one of the female and male terminals of another matching pair of terminals (e.g., the male terminal 124A of the matching pair of female and male terminals 74A, 124A). The other of the female and male terminals (e.g., the female terminal 124A) is then electrically coupled to the negative terminals of all the battery cells via the tie-rod extending between the negative male and female terminals (e.g., tie-rod 114). In this manner, the tie-rod (e.g., tie-rod 114) extending between the negative female and male terminals (e.g., negative female and male terminals 74A, 124A) acts as a negative pass-through terminal for providing a negative power connection to both ends of the battery pack 100.

The remaining matching pairs of female and male terminals (e.g., first pair of female and male terminals 70A, 120A, second pair of female and male terminals 70A, 120A, and female and male terminals 76A, 126A) are selectively electrically coupleable to the positive female and male terminals to form neutral terminal pairs. However, each remaining pair of neutral terminals is electrically coupled to each other via a respective one of the tie-rods. For example, the first and second pair of female and male terminals 70A, 120A are electrically coupled to a respective one of the tie-rods 110, and the female and male terminals 76A, 126A are electrically coupled to tie-rod 116. In this manner, each tie-rod (e.g., tie-rods 110, 116) that extends between respective electrically neutral female and male terminal pairs acts as a neutral pass-through terminal for bypassing the battery cells 102 and providing a neutral power connection for communication of control signals between modules coupled to opposing ends of the power module (e.g., the power consumption module 30 and the power control module 40).

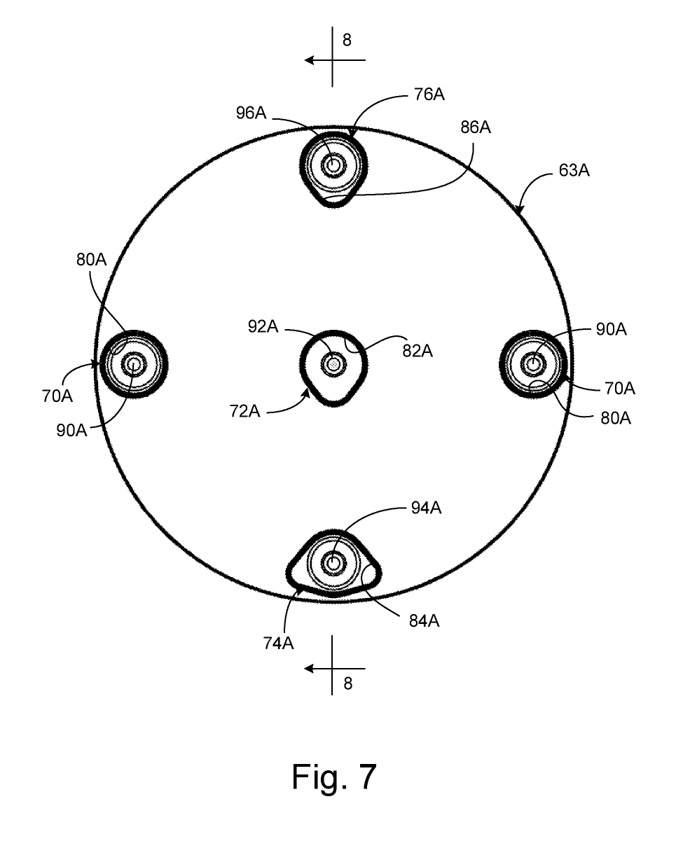

In addition to facilitating electrical coupling between male and female terminals, the tie-rods are configured to secure the end caps 64, 69 and battery cells 104 together into a compact assembly. Generally, the tie-rods are tightenable to draw the end caps 64, 69 together to apply a compressive force against the battery cells 104 and effectively sandwich the battery cells between the end caps. Referring to FIG. 7, the tie-rod 110, being representative of the tie-rods 112, 114, 116, includes an elongate shaft 160 with external threads 162, 163 on respective end portions of the shaft. The external threads 162, 163 are configured to threadably engage internal threads of respective shaft couplings 164, 166. Moreover, the engaged threads 162, 164 are reversed relative to the engaged threads 163, 166 such that when the shaft 160 is rotated in a tightening direction, both the couplings 164, 166 travel axially along the shaft toward each other. The middle or internal tie rod 118 also includes a shaft and shaft couplings. However, in certain implementations, the shaft couplings are permanently fixed to the shafts via soldering, crimping, welding, or other fixation technique. Or alternatively, the couplings are co-formed or co-molded with the shaft to form a one-piece monolithic construction.

During assembly of the battery pack 100, the shaft couplings 164, 166 are inserted through holes formed in the respective female interface recesses and male interface projections. The shaft couplings 164, 166 are then threadably engaged with the shaft 160 and the shaft is rotated in a tightening direction. The shaft coupling 164 includes a stop 168 larger than the opening in the female interface recess, and the portion 170 of the coupling 166 defining the conducting recess 140A has a larger diameter than the opening in the male interface projection. Accordingly, as the shaft 160 is rotated and the couplings 164, 166 are drawn toward each other, the stop 168 and portion 170 contact the openings in the respective recess and projection to prevent further movement of the couplings relative to the end caps 64, 69. Further tightening of the shaft 160 causes the end caps 64, 69 to draw toward each other and compress against the battery cells 104 for securing the end caps against the battery cells. The middle tie-rod 118 is held in place by the end caps 64, 69 (e.g., engagement between the couplings of the middle tie-rod 118 and the openings in the middle recess and projection in the respective end caps).

To maintain the spatial relationship of the battery cells 104 relative each other, each end cap 64, 69 includes a plurality of tabs 65, 66, respectively. Each tab 65, 66 includes two adjacent and inwardly-facing surfaces 180, 182 each having a profile matching an exterior surface of a battery cell 104. With the end caps 64, 69 tightened against the battery cells 104, one of the surfaces 180, 182 of adjacent tabs 65, 66 matingly engage the exterior surface of a respective battery cell 104 to maintain the radial or lateral position of the battery cell. Generally, each battery cell 104 includes exposed positive and negative power terminals on opposing ends. However, in some embodiments, other types of battery cells can be used, such as battery cells with positive and negative power terminals on the same end.

In some embodiments, such as in the illustrated embodiments, the battery pack 100 includes two sets 102 of a plurality of battery cells 104. The two sets 102 are configured in an end-to-end configuration (e.g., in series). For stabilization of the battery pack 100 (e.g., to maintain axial alignment of the battery sets 102 relative to each other), the battery pack includes a spacer plate 150 positioned between the battery sets 102 Like the end caps 64, 69, the spacer plate 150 is made from a non-conductive material and includes a plurality of tabs 154 configured similarly to the tabs 65, 66 to matingly engage the exterior surfaces of the battery cells 104 at end portions opposing the respective end portions engaged with the tabs 65, 66. In this manner, each end of each battery cell 104 of a set is secured by either the tabs 65, 154 or the tabs 66, 154. The tabs 154 include openings 157 that allow the tie-rods to extend through the tabs. The spacer plate 150 facilitates electrical coupling between the two sets of battery cells 104. In one embodiment, the spacer plate 150 includes openings 155 to accommodate direct contact between positive and negative power terminals of axially aligned battery cells 104. In other embodiments, the spacer plate 150 includes circuitry to electrically couple the positive and negative power terminals of axially aligned battery cells.

Although the battery pack 100 of the power module 20 is shown as a rechargeable multi-cell battery pack, in other embodiments, the power source of the power module can be one or more of, for example, a non-rechargeable (e.g., disposable) multi-cell battery pack, single-cell battery pack, capacitor storage device, fuel cell storage device, AC adapter, solar power device, and other similar devices.

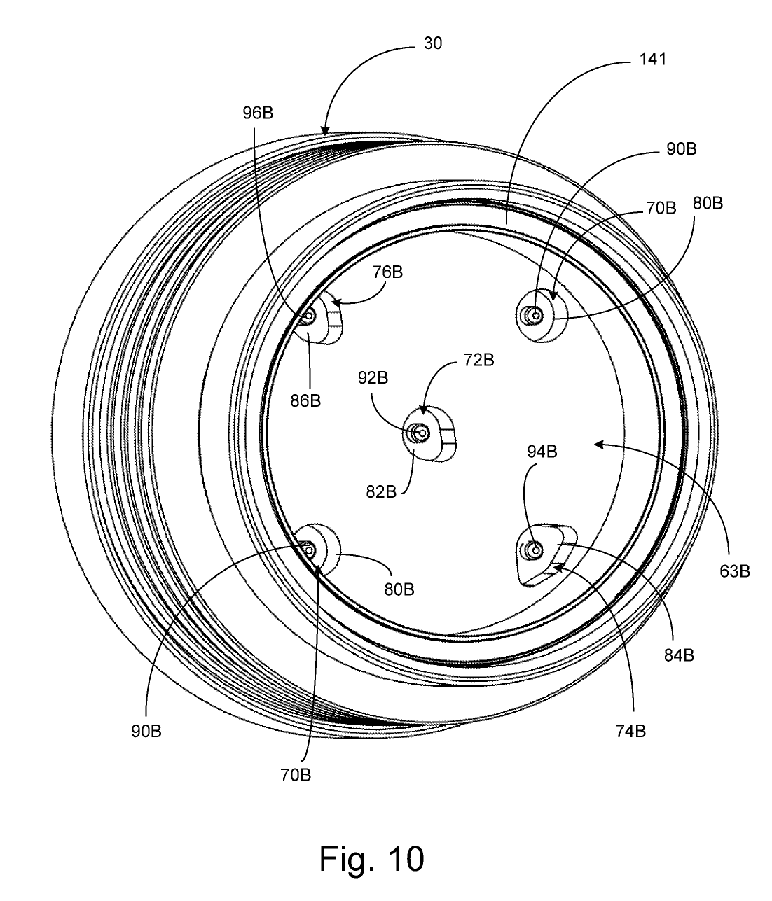

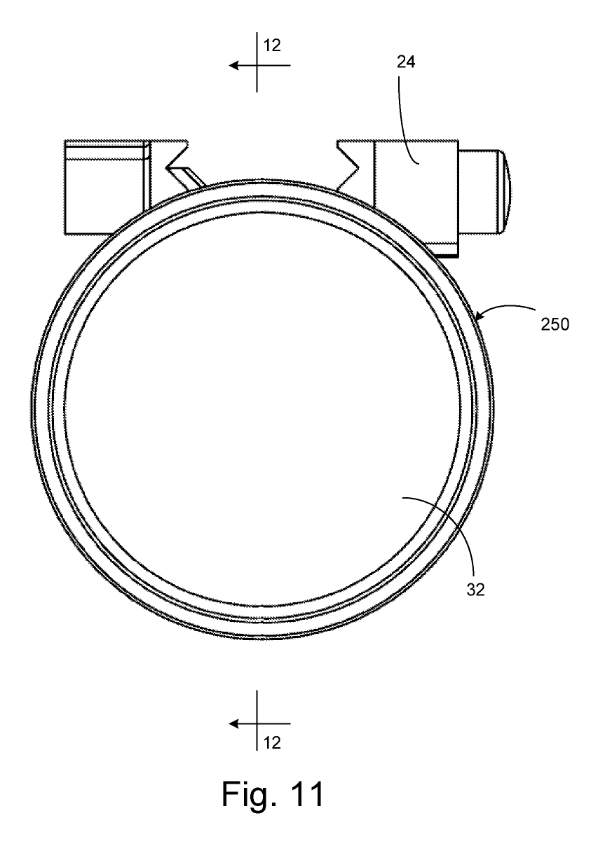

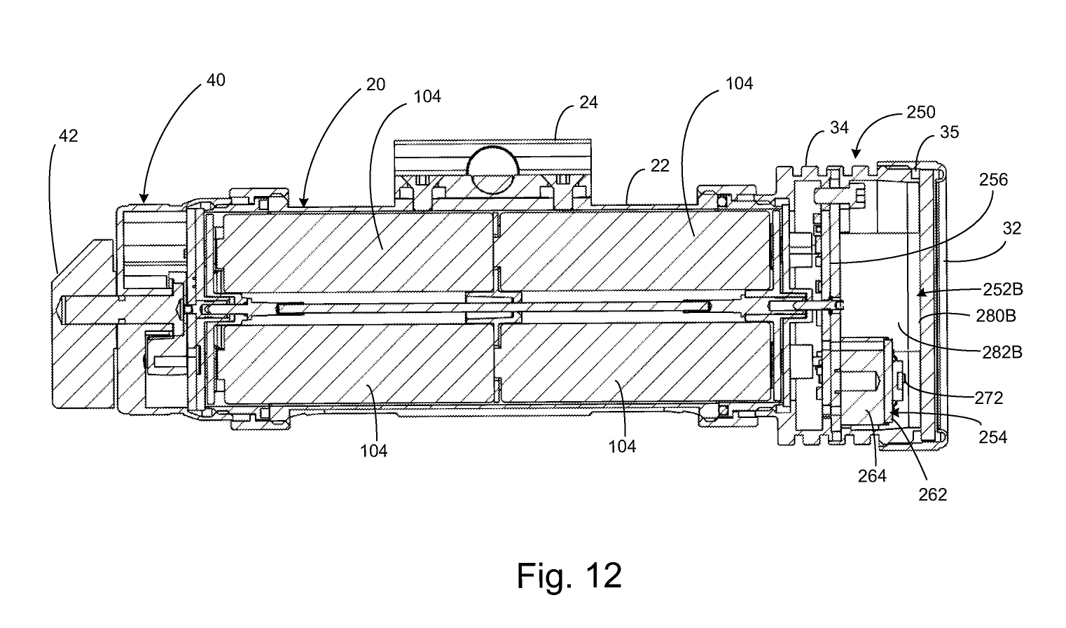

As shown in FIGS. 10-13, the power consumption module 30 is an illumination module with a plurality of illumination elements. The power consumption module 30 includes a female interface 63B configured to matingly engage the male interface 61A of the battery pack 100. Generally, the female interface 63B of the power consumption module 30 is configured in the same manner as the female interface 63A of the battery pack 100. More specifically, the female interface 63B of the power consumption module 30 includes a plurality of female terminals 70B, 72B, 74B, 76B with respective electrically non-conductive recesses 80B, 82B, 84B, 86B and electrically conductive projections 90B, 92B, 94B, 96B. The female terminals 70B, 76B are neutral terminals as at least one of the female terminals 70B, 76B is electrically coupled with power regulating circuitry (not shown) in the power consumption module 30. The female terminal 72B is a positive power terminal as it is electrically coupled to positive power receiving circuitry (not shown) in the power consumption module 30. Similarly, the female terminal 74B is a negative power terminal as it is electrically coupled to negative power receiving circuitry (not shown) in the power consumption module 30

The female interface 63B of the power consumption module 30 matingly engages the male interface 61A of the battery pack 100 via mating engagement between correspondingly shaped and arranged neutral female and male terminals 70B, 120A, positive female and male terminals 72B, 122A, negative female and male terminals 74B, 124A, and neutral female and male terminals 76B, 126A. Engagement between one of the matingly engaged female and male terminals having unique (e.g., non-circular) matching shapes ensures alignment of and electrical connectivity between each of the matingly engaged female and male terminals of the power consumption module 30 and battery pack 100. In other words, the use of at least one female and male terminal having matching electrical polarity and unique shapes ensures the positive, negative, and neutral terminals of the battery pack 100 are electrically connected to the positive, negative, and neutral terminals, respectively, of the power consumption module 30.

According to some embodiments, the power consumption module 30 is a light emitting module 250. As shown in FIGS. 10-13, the light emitting module 250 includes three light emitting diode (LED) devices 252A, 252B, 254 arranged about a base surface 256. Each LED device 252A, 252B, 254 includes a respective mounting surface 260A, 260B, 262 on which a respective LED 270, 272 is mounted (the LED of the LED device 252A is not shown, but can be configured similar to LED 270). The LED devices 252A, 252B are similarly configured, with the mounting surfaces 260A, 260B being approximately on the same plane as the base surface 256. In some implementations, the base surface 256 and mounting surfaces 260A, 260B are the same surface. Each LED 270 can be a visible light or non-visible light (e.g., infrared (IR) or ultraviolet (UV) light) LED. In the illustrated embodiments, the LEDs 270 are non-visible light LEDs. The LED devices 252A, 252B further include respective optic lenses 280A, 280B mounted over the respective LEDs 270. The optic lenses 280A, 280B are secured to a housing 282A, 282B that positions the respective optic lenses 280A, 280B just above the LEDs 270, respectively. The optic lenses 280A, 280B are configured to redirect (e.g., modify) the light emitted from the LEDs 270 into respective focused (e.g., narrow) light beams to illuminate narrow areas or spaces. In certain embodiments, one of the optic lenses 280A, 280B is configured to produce a first narrow beam and the other of the optic lens is configured to produce a second narrow beam that is narrower (e.g., more focused) than the first.

The LED device 254 can include an LED 272 configured to emit a non-visible light, such as an IR or UV light, or a visible light. In the illustrated embodiment, the LED 272 is a non-visible light LED. The LED device 254 does not include an optic lens. Rather, the non-visible light emitted from the LED 272 is an unmodified wide-angle light beam to illuminate a wide area or space. Due to the desired wide angle profile of the LED 272 light beam, the mounting surface 262 of the LED 272 is elevated with respect to the mounting surfaces 260A, 260B of the LEDs 270A, 270B to avoid obstruction of the light beam by the outer rim 35 of the housing 34 and the lens cap 32 of the power consumption module 30. Elevation of the mounting surface 262 can be achieved by mounting the LED 272 on a spacer 264 secured to and extending from the base surface 256.

Although the power consumption module 250 is shown as a light illumination module with light emitting elements, in other embodiments, the power consumption module includes other types of power consuming devices, such as, for example, one or more of lantern devices, GPS devices, radio receivers, radio transmitters, emergency locator beacons, smoke detectors, temperature sensors, wind speed sensors, pressure sensors, humidity sensors, laser-based devices, distance measurement devices, video recording devices, audio recording devices, internet communication devices, cell phone chargers, auxiliary power outlets, electronic storage devices (e.g., flash drive, USB, digital storage, etc.), wireless communication devices, specialized test equipment (e.g., electrical measurement devices, radon gas detectors, etc.), Taser type devices, emergency signal lights, emergency signal audio alarms, radar speed detectors, biometric scanners, dead-man switches (e.g., alarm systems that issue alarm if no motion is detected for a set period of time), altimeters, depth gages, MP3 players, RFID readers, RFID transmitters, and other like devices.

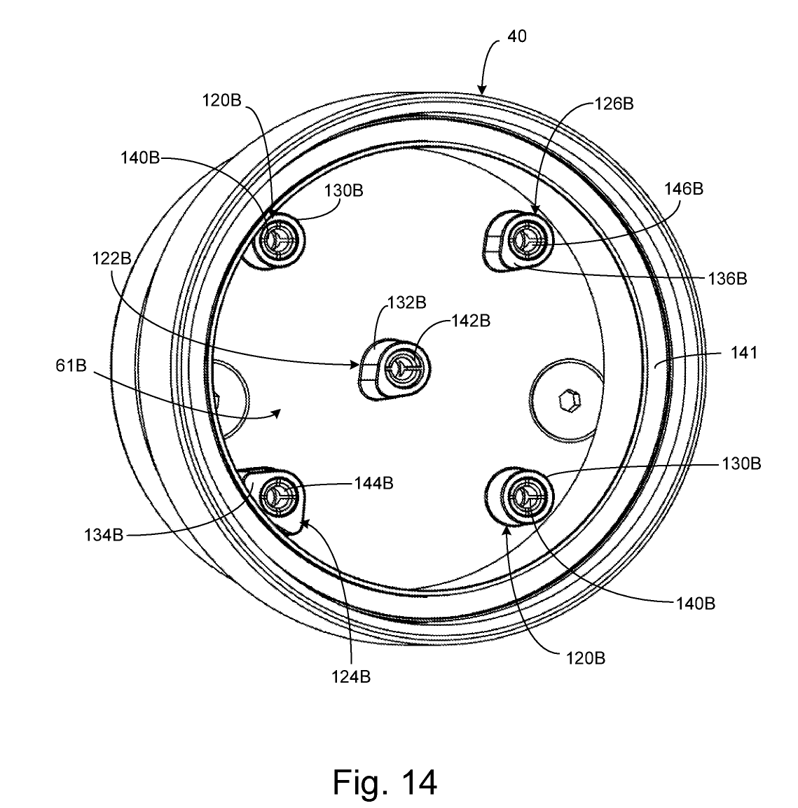

As shown in FIG. 14, the power control module 40 modulates the power consumption modes of the power consumption device via the switch 42. The power control module 40 includes a male interface 61B configured to matingly engage the female interface 63A of the battery pack 100. Generally, the male interface 61B of the power control module 40 is configured in the same manner as the male interface 61A of the battery pack 100. More specifically, the male interface 61B of the power control module 40 includes a plurality of male terminals 120B, 122B, 124B, 126B with respective electrically non-conductive projections 130B, 132B, 134B, 136B and electrically conductive recesses 140B, 142B, 144B, 146B. The male terminals 120B, 126B are neutral terminals as at least one of the male terminals 120B, 126B is electrically coupled with power regulating circuitry (not shown) in the power control module 40. The male terminal 122B is a positive power terminal as it is electrically coupled to positive power receiving circuitry (not shown) in the power control module 40. Similarly, the male terminal 124B is a negative power terminal as it is electrically coupled to negative power receiving circuitry (not shown) in the power control module 40. The power receiving circuitry is electrically coupled to the power regulating circuitry such that the power regulating circuitry regulates the flow of power from the power receiving circuitry to one or more of the neutral terminals 120B, 126B, and thus one or more neutral terminals and neutral lines of interconnected modules (e.g., the neutral pass-through terminals of the battery pack 100 and neutral terminals 70B of the power consumption module 30).

The male interface 61B of the power control module 40 matingly engages the female interface 63A of the battery pack 100 via mating engagement between correspondingly shaped and arranged neutral female and male terminals 70A, 120B, positive female and male terminals 72A, 122B, negative female and male terminals 74A, 124B, and neutral female and male terminals 76A, 126B. Engagement between one of the matingly engaged female and male terminals having unique (e.g., non-circular) matching shapes ensures alignment of and electrical connectivity between each of the matingly engaged female and male terminals of the power control module 40 and battery pack 100. In other words, the use of at least one female and male terminal having matching electrical polarity and unique shapes ensures the positive, negative, and neutral terminals of the battery pack 100 are electrically connected to the positive, negative, and neutral terminals, respectively, of the power control module 40.

Generally, the neutral communication lines established between respective neutral terminals of the modules 20, 30, 40 are used to connect the control functions of the power consumption module or modules. The control function or functions of each power consumption module usable with the portable power module assembly of the present disclosure can be unique or may be the same.

In one implementation of an assembly with an illumination-type power consumption module that has one or multiple light elements (e.g., LEDs) operable in a single ON mode, one of the neutral communication lines of the assembly is coupled to a positive power terminal of the power module and used to send an ON signal (e.g., electrically couples the positive power terminal of the power module with illumination module) to the illumination module when a switch or button is actuated on the power control module. In implementations where the multiple light elements are operable in a plurality of ON modes, one of the neutral communication lines is coupled to a positive power terminal and can be used to send momentary ON signals to a microprocessor in the illumination module. The microprocessor then selects certain modes of operation based on the number of ON signals received or the duration of the ON signal.

In one implementation of an assembly with an illumination-type power consumption module that has one or multiple light elements (e.g., LEDs) operable in a multiple ON modes without a microprocessor, more than one neutral communication line of the assembly can be used to operate the illumination module in different modes. For example, the power control module may include a switch that mechanically selects one or more neutral communication lines to send power to one or more LEDs. For example, in one configuration, a multi-position switch can be adjusted between multiple position with each position be associated with a different power mode. In one position, an ON signal is sent only through a first neutral line to power only a first LED. In another position, an ON signal is sent through first and second neutral lines to power first and second LEDs. In yet another position, an ON signal is sent only through the second neutral line to power only the second LED. With three neutral lines, up to seven different positions can be used for seven different power modes.

Additionally, the multiple common neutral lines established across multiple modules of an assembly as described herein can facilitate the use of multiple power control modules in a single assembly. For example, one control module can use one common neutral line for controlling power to one power consumption module of the assembly and another control module can use another common neutral line for controlling power to another power consumption module of the same assembly.

Further, in some implementations, one or more of the common neutral lines can be used for communication between two or more power consumption devices of the same assembly. For example, one assembly may have a single power control module that controls power to multiple power consumption devices. Also, one power control module may control power to one power consumption device via one neutral line, and the one power consumption device then controls power to a second consumption device via another neutral line (e.g., an alarm module activating an illumination module).

Mating engagement between the respective male and female terminals of the power module 20 (e.g., battery back 100), power consumption module 30, and power control module 40 facilitate co-rotation of the modules. Moreover, because the power module 20 is rotatable relative to the power module housing 22, the power consumption module 30 and power control module 40 likewise are rotatable relative to the housing. Accordingly, the orientation of the power consumption module 30 and power control module 40 can be adjusted independently of the orientation of the housing 22. For example, when desired, the orientation of the power consumption module 30 and power control module 40 relative to an object (e.g., the ground or a firearm to which the assembly 10 is attached) can remain fixed or be adjusted while the orientation of the housing 22 is adjusted or remains fixed, respectively. Such functionality can be particularly advantageous as use of the assembly 10 is, for example, alternated between right-handed and left-handed configurations or between different users with different preferences.

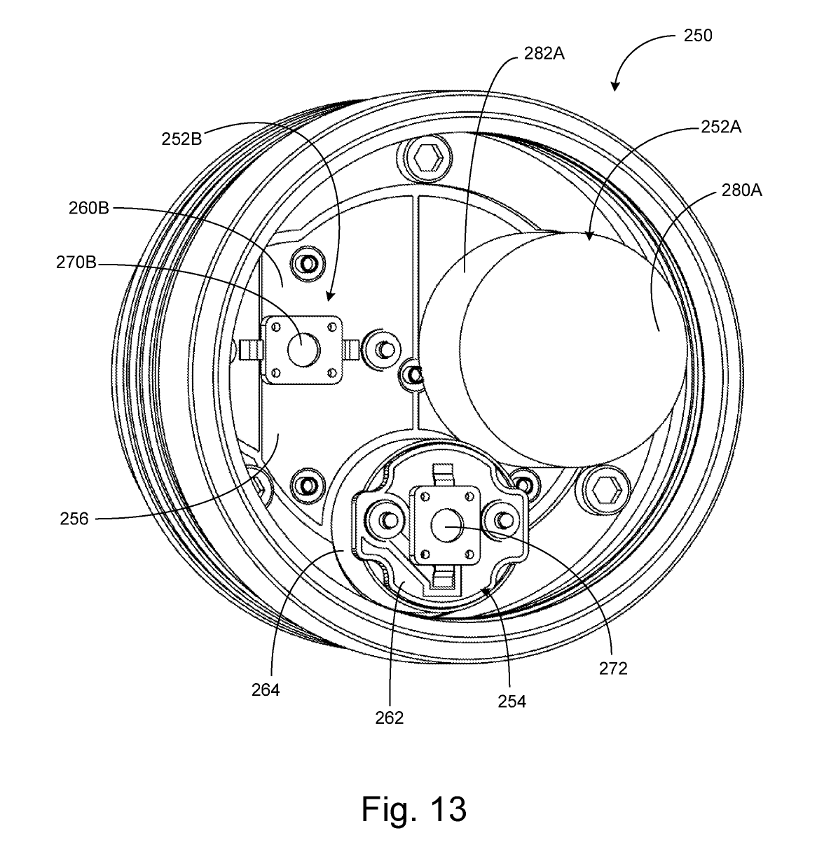

As discussed above, the mating male and female interfaces of the individual, self-contained interconnectable modules of the portable power module assembly 10 facilitate easy modification and reconfiguration of the assembly without deformation or alteration of the modules while maintaining a positive power supply, negative power supply, and neutral power control across all modules of the assembly. The keyed or unique shape of one set of mating male and female terminals of the interfaces ensures proper electrical alignment between all the modules of the assembly. Accordingly, the present disclosure supports a power module system including any of a plurality of modules in any of a plurality of configurations with each module being removably mechanically and electrically interconnected with one or two other modules via mating engagement between the male and female interfaces to form a desired configuration. Although the possible types and order of modules is infinite, certain system configurations are shown schematically in FIGS. 13-19 as examples for illustrating the flexibility, versatility, and possibilities of the system.

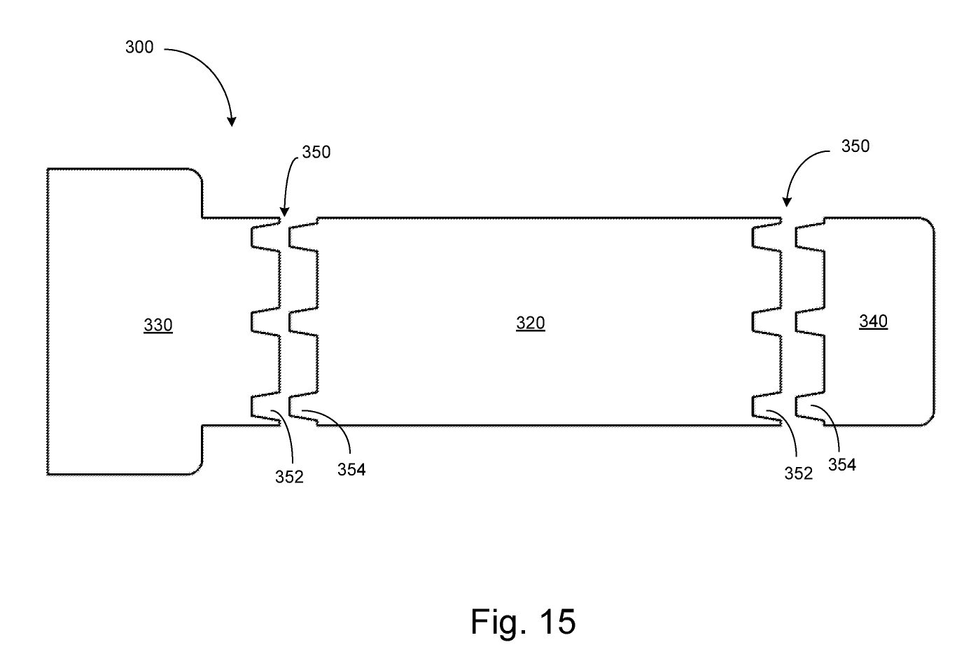

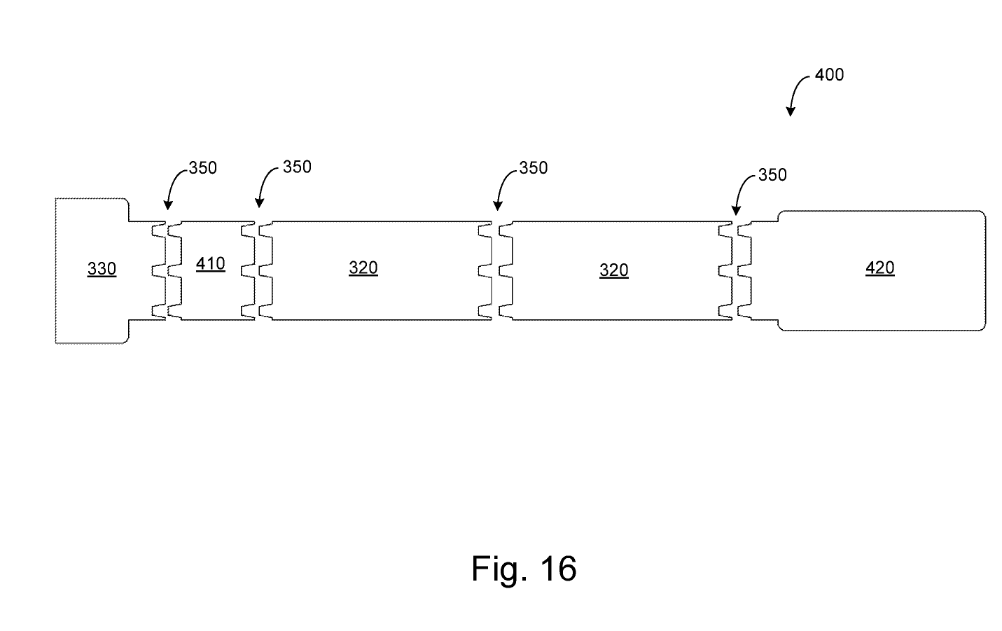

According to FIG. 15, the assembly 10 as discussed above is shown schematically as assembly 300, which provides a reference point for the assemblies of FIGS. 16-21. For example, the power module 320 of the assembly 300 is shown as a common module throughout all of the assemblies of FIGS. 15-21. In practice, such a flexible approach is desirable, as a single power module can be used in a plurality of configurations for powering a plurality of power consumption devices. The removable interconnection 350 between the male and female interfaces of the modules, as described above in detail, is shown schematically with the male interface 354 of the interconnection 350 shown as a series of projections and the female interface 352 shown as a series of recesses. The power consumption device 330 can be any type of power consumption device, such as those described above. However, for purposes of illustration, the power consumption device 330 of the assemblies of FIGS. 15-21 is an illumination module 330 that has light-emitting elements for emitting light. Similar to assembly 10, the assembly 300 also includes an end-mounted power control or switch module 340. As shown, the power module 320 is positioned between the illumination module 330 and end-mounted power control or switch module 340.

Referring to FIG. 16, a portable power module assembly 400 includes a middle-mounted switch module 410 positioned between and mated to the power and illumination modules 320, 330, instead of mated to an end of the power module away from the illumination module as with the end-mounted switch module 340. The assembly 400 also includes a second power module 320 positioned between and mated to a lantern module 420 and the first power module 320. The two power modules 320 being in series acts to increase the voltage output of the power modules. The lantern module 420 may include a lantern-type light-emitting element (e.g., a bulb) and an integral switch that is actuatable by a user to activate and regulate the lantern-type light-emitting element. Alternatively, instead of an integral switch, the assembly 400 could include a separate end-mounted switch module 340 or middle-mounted switch module 410 that regulates power to the lantern module 420.

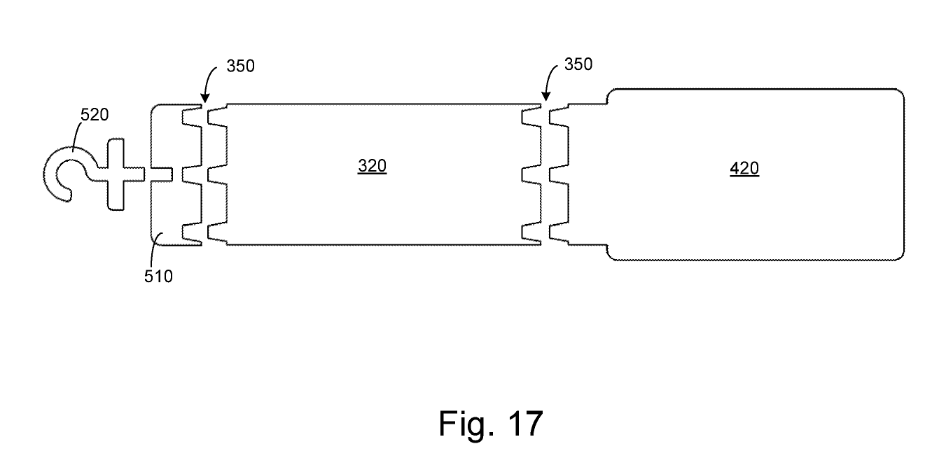

Referring to FIG. 17, a portable power module assembly 500 includes the power module 320 and lantern module 420 with integrated switch. To close the electrical loop on the free end of the power module 320, the assembly 500 includes an end cover module 510. The end cover module 510 includes a female interface to mate with the male interface of the free end of the power module 320. In certain implementations, the end cover module 510 may include a mounting element 520 removably attached to the end cover module. The mounting element 520 may be used to facilitate attachment of the assembly 500 to and detachment of the assembly from an object, such as a utility belt, helmet, vehicle, etc.

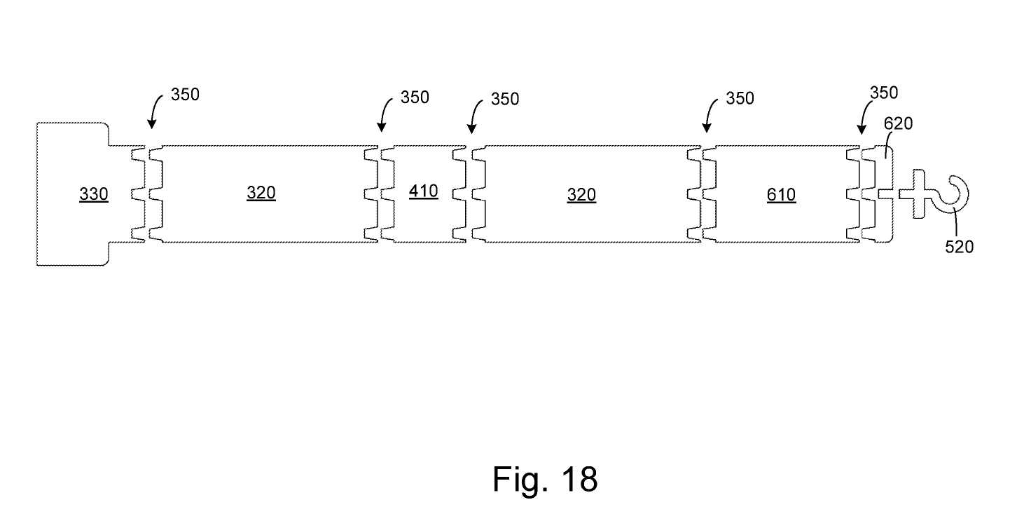

Referring to FIG. 18, a portable power module assembly 600 includes two power modules 320 with a middle-mounted switch module 410 positioned between and mated to the power modules. The assembly 600 also includes an illumination module 330 mated to a first of the power modules 320 at a first end of the assembly and a middle-mounted power consumption module 610 mated to a second of the power modules 320. An end cover module 620 includes a male interface to mate with the female interface of the power consumption module 610 Like the end cover module 510, the end cover module 620 includes a mounting element 520 removably attached to the end cover module 620. The middle-mounted switch module 410 of the assembly 600 is configured to regulate power to both the illumination module 330 and the middle-mounted power consumption module 610. The power consumption module 610 can include any of various power consumption devices as discussed above and equivalents.

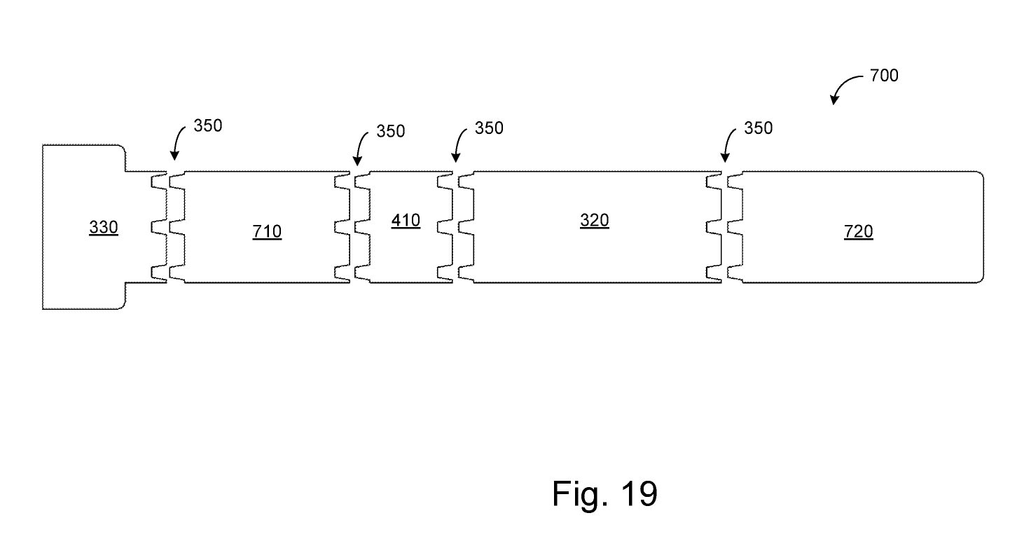

Referring to FIG. 19, a portable power module assembly 700 includes a power module 320, a middle-mounted power consumption module 710, and an illumination module 330. The assembly 700 also includes a middle-mounted switch module 410 positioned between and mated to the power module 320 and middle-mounted power consumption module 710. The illumination module 330 is mated to an end of the module 710, such that the module 710 is positioned between and mated to the switch module 410 and illumination module 330. Additionally, the assembly 700 includes a non-powered module 720 coupled to a free end of the power module 320 away from the middle-mounted switch module 410. The non-powered module 720 includes some circuitry to close the loop between the positive and negative power terminals of the assembly, but does not include any power consumption devices. The module 720 can include any of various non-powered devices, such as, for example, generic storage compartments, water filters, pepper spray dispensers, microscopes, telescope type devices, flare guns, test sample containers, kits (e.g., first aid, snake bite, medical procedure, water test, fire starter, finger printing, sharpening, etc.), multi-tool systems, whistles, or other audio signal devices, compasses, and smoke generators.

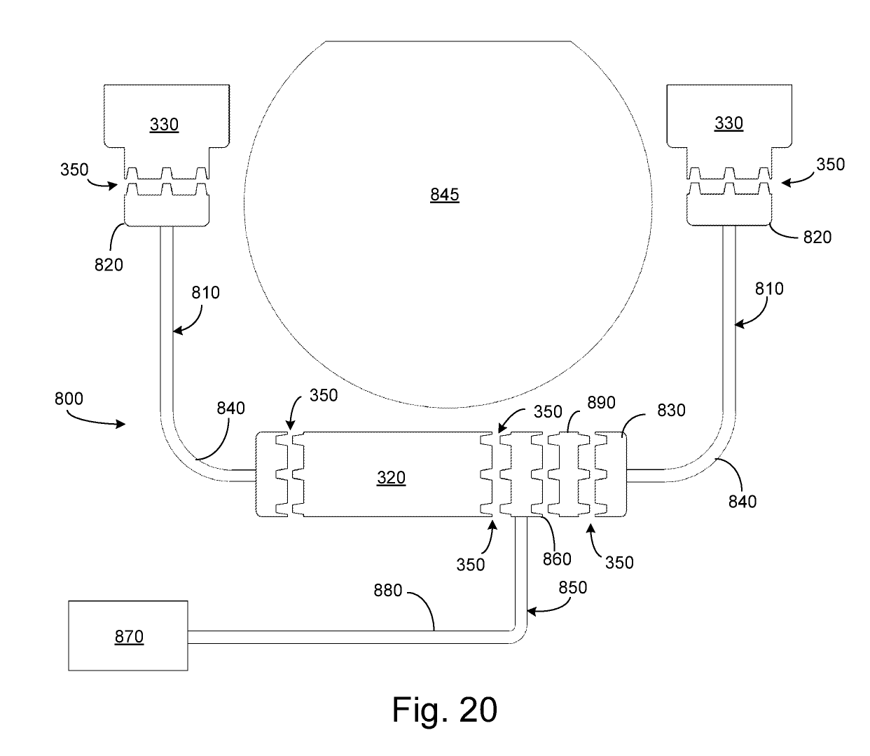

Referring to FIG. 20, a portable power module assembly 800 includes a power module 320 positioned between and mated to a remote adapter module 810 and a remote switch module 850. The remote adapter module 810 is configured to remotely couple an illumination module 330 to the power module 320. The module 810 includes a male interface portion 820 coupled to a female interface portion 830 via a power line or cable 840. The male interface portion 820 mates with the female interface of the illumination module 330 and the female interface portion 830 mates with the male interface of the power module 320. The cable 840, which preferably is a flexible cable, includes a positive power line, negative power line, and at least one neutral communication line corresponding to the positive power, negative power, and at least one neutral terminals of the interface 350. The remote illumination head 330 is mounted to an object 845, such as the helmet of a firefighter, police officer, military personnel, or other service provider.

The remote switch module 850 includes an interface portion 860 with a male interface for mating with the female interface of the power module 320 and a female interface for mating with the male interface of a male-to-male adaptor module 890. Further, the remote switch module 850 includes a power line or cable 880 similar to cable 840 that electrically couples the interface portion 860 with a remotely mounted switch 870. The switch 870 can be mounted to an object, such as a person, in a highly accessible location (e.g., on the chest of the person) and the power module 320, and associated modules directly mated with the power module, can be mounted in a location causing the least interference with movement of the person (e.g., the back of the person). In certain implementations, the switch 870 is push button that toggles between ON and OFF positions. A second remote adaptor module 810 and illumination module 330 can be mated to the male-to-male adaptor module 890 with the illumination module mounted to the object 845 (e.g., at a location opposite the first illumination module). Actuation of the remote switch 870 modulates power from the power source 320 to the first and second illumination modules 330. The assembly 800 is particularly convenient in firefighting situations where the firefighter has no free hands for grasping a flashlight and requires quick and easy actuation of a switch for turning a light source on and off.

Although not shown, the assembly 800 may also include a power mode selector module with a switch that is actuatable to adjust the power mode of the illumination modules 330 between a plurality of modes. The remote switch module 850 can then behave as a power interrupter to control a main power supply to the power mode selector such that when the remote switch module 850 is turned ON, the illumination modules 330 operate in the power mode selected by the power mode selector module. In this manner, a user need not toggle from a power OFF position to a desired power mode every time the device is turned ON. Rather, this allows a user to set (e.g., keep) the illumination modules 330 in a desired setting and requires only a simple toggling of the remote switch 870 from OFF to ON to activate the illumination modules in the desired setting.

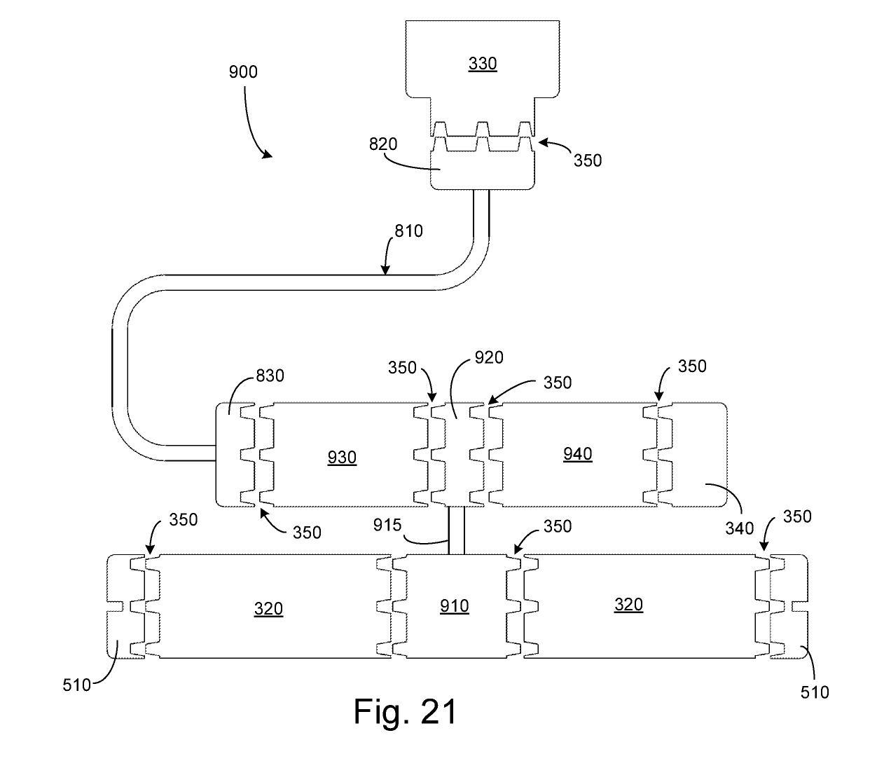

Referring to FIG. 21, a portable power module assembly 900 includes a power module 320 positioned between and mated to an end cover module 510 and one male interface of a spare battery switch module 910. Additionally, the assembly 900 includes a spare power module 320 mated to a second male interface of the spare battery switch module 910. The spare battery switch module 910 is operable to toggle the power supply for the assembly between the two power modules 320. The spare power module 320 is mated to a second end cover module 510. The spare battery switch module 910 includes a power line or cable 915 electrically coupled to a remote adapter power module 920. The power line 915 facilitates the mounting of the power modules 320 remote from the remote adapter power module 920 and any modules directed mated to the module 920. For example, the assembly 900 includes an emergency locator module 930 mated to a female interface of the remote adapter power module 920 and a gas detection module 940 mated to a male interface of the module 920. Utilizing the remote adapter power module 920 allows the modules 930, 940 to be mounted to an object (e.g., a person) remote from the power sources 320.

The emergency locator module 930 is configured to transmit a beacon signal indicating the location of the wearer of the module 930. The gas detection module 940 is configured to detect the presence of dangerous levels of a gas and warn a wearer of the module 940 with a visual or audible alarm. Mated to the gas detection module 940 is an end-mounted switch module 340 operable to control power to a remotely mounted illumination module 330, which is electrically coupled to the emergency locator module 930 via a remote adaptor module 810. The assembly 900 is particularly suitable in mining applications where remote illumination, emergency locating capability, and dangerous gas detection capability is desirable.

As already mentioned, the above-described assemblies are merely exemplary of any of a plurality of other assemblies with any of a plurality of modules. Further, the male-to-female interconnections 350 of the assemblies can be reversed to be female-to-male interconnections. Additionally, any one or more modules of the above assemblies can be omitted. In some implementations, modules adjacent the omitted module or modules are mated together to effectively “shorten” the assembly. Alternatively, in other implementations, one or more modules can replace the omitted module or modules to alter the configuration of the assemblies as desired to accommodate different applications. However, in some embodiments, any middle-mounted modules, including switch modules, power consumption modules, non-powered modules, must include the pass-through electrical circuitry (e.g., with associated female or male interfaces) discussed in detail above. In this manner, in such embodiments, the various modules of the portable power module assembly are interchangeable with each other in any of a plurality of sequences or order to enhance the flexibility and versatility of the assembly.

The present subject matter may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus, comprising:
a power module comprising a power source;
a power consumption module configured to consume power from the power source; and
a power control module configured to selectively regulate power from the power source to the power consumption module;
wherein each of the power module, power consumption module, and power control module comprises a positive power terminal, a negative power terminal, and at least one neutral terminal, the power module, power consumption module, and power control module each being removably interconnected adjacently to at least another of the power module, power consumption module, and power control module via engagement between the positive power terminals of the at least one adjacent module, the negative power terminals of the at least one adjacent module, and the neutral terminals of the at least one adjacent module; and
wherein the positive power terminals of the power module, power consumption module, and power control module are electrically coupleable to each other via the engagement between the positive power terminals of adjacent modules, the negative power terminals of the power module, power consumption module, and power control module are electrically coupleable to each other via the engagement between the positive power terminals of adjacent modules, and the neutral terminals of the power module, power consumption module, and power control module are electrically coupleable to each other via the engagement between the neutral power terminals of adjacent modules.

2. The apparatus of claim 1, wherein the power control module selectively regulates power from the power source to the power consumption module via communication through the neutral terminals of at least the power consumption module and the power control module.

3. The apparatus of claim 2, wherein the power module is positionable between and removably interconnected adjacently to the power consumption module and the power control module.

4. The apparatus of claim 2, wherein the power control module is positionable between and removably interconnected adjacently to the power module and power consumption module.

5. The apparatus of claim 2, wherein the control module comprises a switch selectively actuatable between at least two positions associated with at least two power regulating modes.

6. The apparatus of claim 1, wherein the power consumption module comprises a light emitting element.

7. The apparatus of claim 1, wherein the power consumption module is a first power consumption module, the apparatus further comprising a second power consumption module, and wherein the second power consumption module is removably interconnected adjacently to at least one of the power module, first power consumption module, and power control module in any of a plurality of sequences.

8. The apparatus of claim 7, wherein the first power consumption module is interchangeable with the second power consumption module.

9. The apparatus of claim 1, wherein the power control module is a first power control module, the apparatus further comprising a second power control module configured to regulate power from the power source to the first power control module, and wherein the second power control module is removably interconnected adjacently to at least one of the power module, first power consumption module, and power control module in any of a plurality of sequences.

10. The apparatus of claim 9, wherein the second power control module comprises a power interrupter portion and a switch portion, the power interrupter portion comprising the positive power terminal, negative power terminal, and at least one neutral terminal of the second power control module, and the switch portion being operable to control operation of the power interrupter portion and being positionable remotely relative to the power interrupter portion.

11. The apparatus of claim 1, wherein the power module is a first power module, the apparatus further comprising a second power module removably interconnected adjacently to the first power module.

12. The apparatus of claim 1, wherein each of the power module, power consumption module, and control module is defined about a central axis, and wherein the central axes of the power module, power consumption module, and control module are coaxially alignable.

13. The apparatus of claim 1, wherein the engaged positive power terminals, negative power terminals, and neutral power terminals of adjacent modules comprise respective first and second positive power terminals, first and second negative power terminals, and first and second neutral terminals, the first terminals each comprising one of a male terminal and female terminal, and the second terminals each comprising the other of the male terminal and female terminals, wherein the male terminals each comprise a non-electrical projection and an electrical recess positioned within the projection, and wherein the female terminals each comprise a non-electrical recess and an electrical projection positioned within the recess, wherein engagement between male and female terminals comprises corresponding mating engagement of the non-electrical projection with the non-electrical recess and mating engagement of the electrical projection with the electrical recess.

14. The apparatus of claim 1, wherein the positive power terminals of the power module, power consumption module, and power control module are coaxially alignable, the negative power terminals of the power module, power consumption module, and power control module are coaxially alignable, and the neutral terminals of the power module, power consumption module, and power control module are coaxially alignable.

15. The apparatus of claim 14, wherein at least one of the positive power terminals, negative power terminals, and neutral terminals of the respective power module, power consumption module, and power control module is shaped differently than the others of the positive power terminals, negative power terminals, and neutral terminals of the respective power module, power consumption module, and power control module, and wherein engagement between the differently-shaped terminals ensures relative coaxial alignment of the positive power terminals, negative power terminals, and neutral terminals.

16. The apparatus of claim 1, wherein the power module, power consumption module, and power control module are removably interconnected adjacently to at least another of the power module, power consumption module, and power control module in any of a plurality of sequences.

17. The apparatus of claim 1, wherein the power module, power consumption module, and control module are substantially cylindrically shaped and stackable in an end-to-end configuration, wherein the positive power terminals, negative power terminals, and neutral terminals are formed in the ends of the modules.

18. The apparatus of claim 1, wherein the power module comprises a housing within which the power source is positioned, and wherein when removably interconnected the power source, power consumption module, and power control module are co-rotatable relative to the housing of the power module.

19. The apparatus of claim 18, wherein the housing of the power module is symmetrical.

20. The apparatus of claim 18, wherein each of the power module, power consumption module, and power control module comprises at least one connection element separate and distinct from the positive power terminal, negative power terminal, and at least one neutral terminal, the power module, power consumption module, and power control module each being removably and securely interconnected adjacently to at least another of the power module, power consumption module, and power control module via engagement between respective connection elements, the at least one connection element configured to selectively lock in place the rotational orientation of the power module, power consumption module, and power control module relative to the housing of the power module.

21. The apparatus of claim 20, wherein the at least one connection element comprises one of a lock ring and lock ring engagement feature, wherein engagement between respective connection elements comprises engagement between a respective lock ring and lock ring engagement feature.

22. The apparatus of claim 21, wherein the power module comprises a housing within which the power source is positioned, the housing extending between a first end and a second end, wherein the first end comprises a first lock ring engagement feature and the second end comprises a second lock ring engagement feature, and wherein the power consumption module comprises a first lock ring and the power control module comprises a second lock ring, the first lock ring being engageable with the first lock ring engagement feature to removably and securely interconnect the power module and the power consumption module, and the second lock ring being engageable with the second lock ring engagement feature to removably and securely interconnect the power module and the power control module.

23. The apparatus of claim 1, wherein the power module, power consumption module, and power control module are removably interconnected via respective couplings each comprising a plurality of interlocking projections and recesses.

24. An apparatus for powering a power consumption device, comprising:
at least one set of a plurality of battery cells positioned adjacent and parallel to each other, the at least one set of a plurality of battery cells comprising a first end and second end opposing the first end, each battery cell comprising a positive terminal and a negative terminal;
a first end cap positioned at the first end of the at least one set of a plurality of battery cells;
a second end cap positioned at the second end of the at least one set of a plurality of battery cells; and
a plurality of tie rod terminals secured to and extending between the first end cap and the second end cap, the plurality of tie rod terminals being tightenable to draw the first and second end caps together and secure the at least one set of a plurality of battery cells between the first and second end caps, wherein a first of the plurality of tie rod terminals is electrically coupled to the positive terminals of the battery cells, a second of the plurality of tie rod terminals is electrically coupled to the negative terminals of the battery cells, and a third of the plurality of tie rod terminals is electrically neutral.

25. The apparatus of claim 24, wherein:
the first end cap comprises a plurality of recesses;
a first end portion of each of the plurality of tie rod terminals secured to the first end cap extends into a respective recess of the first end cap, the first end portions configured to receive female electrical terminals;
the second end cap comprises a plurality of projections; and
a second end portion of each of the plurality of tie rod terminals secured to the second end cap extends through a respective projection of the first end cap, the second end portions configured to receive male electrical terminals.

26. The apparatus of claim 24, wherein at least one of the plurality of recesses and projections has a first cross-sectional shape, and at least another of the plurality of recesses and projections has a second cross-sectional shape different that the first cross-sectional shape, and wherein a respective one of the plurality of tie rods extends between the at least one of the plurality of recesses and projections with the first cross-sectional shape, and a respective one of the plurality of tie rods extends between the at least one of the plurality of recesses and projections with the second cross-sectional shape.

27. The apparatus of claim 24, wherein:
the at least one set of a plurality of battery cells comprises an interior space defined between the plurality of battery cells and a plurality of exterior spaces each defined between respective adjacent battery cells of the plurality of battery cells;
the first of the plurality of tie rod terminals extends through the interior space;
the second of the plurality of tie rod terminals extends through a respective one of the plurality of exterior spaces; and
the third of the plurality of tie rod terminals extends through another respective one of the plurality of exterior spaces.

28. The apparatus of claim 24, wherein the first and second end caps each have a substantially circular outer periphery of equal dimensions, and wherein the at least one set of a plurality of battery cells and plurality of tie rod terminals are confined within the substantially circular outer peripheries of the first and second caps.

29. The apparatus of claim 24, wherein:
the at least one set of a plurality of battery cells comprises at least a first and second set of a plurality of battery cells each comprising a first end and a second end;
the apparatus further comprises a spacer plate positioned between the first and second set of a plurality of battery cells; and
the plurality of tie rod terminals extend through the spacer plate.

30. The apparatus of claim 24, wherein the first and second end caps each comprises a plurality of battery spacing tabs configured to engage the plurality of battery cells and maintain the battery cells in a fixed position relative to the first and second end caps.

31. The apparatus of claim 24, further comprising a housing defining an interior channel within which the at least one set of a plurality of battery cells is positionable, the housing being configured to be secured to the power consumption device, wherein a diameter of the interior channel is approximately equal to a diameter of the first and second end caps.

32. The apparatus of claim 31, wherein the diameter of the interior channel is approximately equal to a maximum distance between the outermost peripheries of the plurality of battery cells.

33. An apparatus for emitting light, comprising:
a portable power source;
a light emitting module communicable in power receiving communication with the portable power source, the light emitting module comprising a first light emitting diode (LED), a second LED, and a third LED, wherein the first LED comprises a first optic lens for producing a first modified light beam, the second LED comprises a second optic lens for producing a second modified light beam narrower than the first modified light beam, and the third LED is without an optic lens and produces an unmodified light beam wider than the first modified light beam.

34. The apparatus of claim 33, wherein the first, second, and third LEDs each comprises a non-visible light LED.

35. The apparatus of claim 33, wherein the mounting plane of the third LED is elevated relative to the mounting planes of the first and second LEDs.
